(19) United States
(12) Patent Application Publication
(10) Pub. No.: US 2016/0194753 A1
(43) Pub. Date: Jul. 7, 2016

(54) SiC-FILM FORMATION DEVICE AND METHOD FOR PRODUCING SiC FILM

(71) Applicant: SHOWA DENKO K.K., Tokyo (JP)

(72) Inventors: Daisuke MUTO, Chichibu-shi, Saitama (JP); Yusuke KIMURA, Chichibu-shi, Saitama (JP); Tomoya UTASHIRO, Kawasaki, Kanagawa (JP); Seiichi TAKAHASHI, Midori-ku, Chiba (JP); Kenji MOMOSE, Chichibu-shi, Saitama (JP)

(73) Assignee: SHOWA DENKO K.K., Tokyo (JP)

(21) Appl. No.: 14/655,822

(22) PCT Filed: Dec. 11, 2013
(86) PCT No.: PCT/JP2013/083252

§ 371 Date: Jun. 26, 2015

(30) Foreign Application Priority Data
Dec. 27, 2012 (JP) 2012-285157
Dec. 27, 2012 (JP) 2012-285158

(51) Int. Cl. C23C 16/32; C23C 16/46; C23C 16/455

(52) U.S. Cl. CPC C23C 16/325; C23C 16/45502; C23C 16/45519; C23C 16/46

(57) ABSTRACT

A CVD device including: a chamber containing a substrate having a SiC-film formation surface; a heating mechanism for heating the substrate from a direction opposite the film formation surface; a third supply space (231) for supplying a third raw-material gas containing carbon in a direction (X) toward the substrate from the lateral side of the substrate; a second supply space (221) for supplying a second raw-material gas containing silicon in the direction (X) from the lateral side of the substrate toward the side farther than the third raw-material gas when viewed from the film formation surface; and a blocking gas supply section for supplying a blocking gas for suppressing the upward movement of the third raw-material gas and the second raw-material gas in a second direction from the side facing the film formation surface toward the film formation surface.

### TECHNICAL FIELD

The present invention relates to an SiC-film formation device that forms an SiC film on a substrate, and a method for producing the SiC film.

### BACKGROUND ART

As a method for forming an SiC film on a substrate, a chemical vapor deposition method (hereinafter, referred to as a CVD method) is known. In a CVD device that forms an SiC film on a substrate by the CVD method, the substrate is contained in a reaction chamber, a raw-material gas, such as a carbon-containing gas and a silicon-containing gas, that serves as a raw material for the film is supplied to the inside of the reaction chamber, and the substrate is heated to decompose the carbon-containing gas and the silicon-containing gas by heat to cause reaction, to thereby deposit the SiC film on the substrate.

As a conventional art described in a gazette, there is a technique that supplies a raw-material gas, such as an SiH₄ gas and a C₃H₃ gas, to a processing container, which contains a processing substrate in such a manner that a main surface thereof faces upward, from a side of the processing substrate, to thereby cause epitaxial growth of a film containing Si and C as main ingredients on the processing substrate (refer to Patent Document 1).

### CITATION LIST

### Patent Literature

Patent Document 1: Japanese Patent Application Laid-Open Publication No. 2012-178613

### SUMMARY OF INVENTION

### Technical Problem

In general, it is known that thermal properties are different between the silicon-containing gas and the carbon-containing gas. Then, when the SiC film is formed on the substrate by the above-described CVD method, since susceptibility to thermal decomposition is different between the silicon-containing gas and the carbon-containing gas, there is apprehension that a concentration ratio of a growing species generated by the carbon-containing gas to a growing species generated by thermal decomposition of the silicon-containing gas becomes uneven on the substrate. This changes the ratio between carbon and silicon on the substrate, and there is apprehension that film quality of the SiC film formed on the substrate is degraded.

The present invention has an object to suppress degradation of film quality of an SiC film formed on a substrate.

### Solution to Problem

An SiC-film formation device according to the present invention includes: a container chamber that has an interior space, and contains a substrate so that an SiC-film formation surface thereof is exposed to the interior space; a heating unit that heats the substrate from a direction opposite to the SiC-film formation surface; a carbon raw-material gas supply unit that supplies the interior space with a carbon raw-material gas containing carbon, which serves as a material for the SiC film, along a first direction from a lateral side of the substrate toward the substrate; a silicon raw-material gas supply unit that supplies the interior space with a silicon raw-material gas containing silicon, which serves as a material for the SiC film, along the first direction from the lateral side of the substrate toward a side farther than the carbon raw-material gas when viewed from the SiC-film formation surface of the substrate; and a blocking gas supply unit that supplies the interior space with a blocking gas along a second direction from a side facing the SiC-film formation surface toward the SiC-film formation surface, the blocking gas suppressing movement of the carbon raw-material gas and the silicon raw-material gas toward an upstream side in the second direction.

In the SiC-film formation device like this, there is further provided an assist gas supply unit that supplies the interior space with an assist gas along the first direction from the lateral side of the substrate toward at least one of a side closer than the carbon raw-material gas and a side farther than the silicon raw-material gas when viewed from the SiC-film formation surface of the substrate, the assist gas assisting the carbon raw-material gas and the silicon raw-material gas in moving toward the first direction. Moreover, the carbon raw-material gas contains propane gas, the silicon raw-material gas contains monosilane gas, and the blocking gas contains hydrogen gas.

Moreover, from another viewpoint, an SiC-film formation device according to the present invention includes: a container chamber that has an interior space, and contains a substrate on a lower side in the interior space so that an SiC-film formation surface thereof faces upward; and a raw-material gas supply section that supplies the interior space of the container chamber with a raw-material gas, which serves as a material for the SiC film, wherein the container chamber includes: a heater that heats the substrate; and an inert gas supply section that supplies the interior space with an inert gas, which is inactive for the raw-material gas, along a second direction from an upper side toward a lower side, and the raw-material gas supply section includes: a carbon raw-material gas supply route that supplies the interior space with a carbon raw-material gas containing carbon, which serves as a material for the SiC film, along a first direction from a lateral side of the substrate toward the substrate; and a silicon raw-material gas supply route that is placed above the carbon raw-material gas supply route and supplies the interior space with a silicon raw-material gas containing silicon, which serves as a material for the SiC film, along the first direction.

In the SiC-film formation device like this, the raw-material gas supply section further includes a cooling unit that cools the raw-material gas to be supplied to the interior space from the carbon raw-material gas supply route side.

Moreover, the raw-material gas supply section further includes: a first assist gas supply route that is provided below the carbon raw-material gas supply route and supplies a first assist gas along the first direction, the first assist gas assisting the carbon raw-material gas in moving toward the first direction; and a second assist gas supply route that is provided above the silicon raw-material gas supply route and supplies a second assist gas along the first direction, the second assist gas assisting the silicon raw-material gas in moving toward the first direction.

Further, from another viewpoint, a method for producing an SiC film according to the present invention includes: heating a substrate, which is contained in a container chamber having an interior space so that an SiC-film formation surface thereof is exposed to the interior space, from a direction opposite to the SiC-film formation surface; supplying the interior space with a carbon raw-material gas containing carbon, which serves as a material for the SiC film, along a first direction from a lateral side of the substrate toward the substrate; supplying the interior space with a silicon raw-material gas containing silicon, which serves as a material for the SiC film, along the first direction from the lateral side of the substrate toward a side farther than the carbon raw-material gas when viewed from the SiC-film formation surface of the substrate; and supplying the interior space with a blocking gas along a second direction from a side facing the SiC-film formation surface toward the

SiC-film formation surface, the blocking gas suppressing movement of the carbon raw-material gas and the silicon raw-material gas toward an upstream side in the second direction.

### Advantageous Effects of Invention

According to the present invention, it is possible to suppress degradation of film quality of an SiC film formed on a substrate.

### BRIEF DESCRIPTION OF DRAWINGS

FIG. 1 is an entire configuration diagram of a CVD device to which an exemplary embodiment is applied;

FIG. 2 is a perspective view of a substrate onto which a film is laminated and a loading body on which the substrate is loaded, which are used in the CVD device;

FIG. 3 is a virtual cross-sectional view of a reaction container in the CVD device;

FIG. 4 is a IV-IV cross-sectional view in FIG. 3;

FIG. 5 is a V-V cross-sectional view in FIG. 3;

FIG. 6 is a diagram for illustrating various dimensions in the reaction container;

FIG. 7 is a virtual cross-sectional view of a raw-material gas supply section to which the exemplary embodiment is applied;

FIG. 8 is an VIII-VIII cross-sectional view in FIG. 7;

FIG. 9A is a IXA-IXA cross-sectional view in FIG. 7, and FIG. 9B is an enlarged view of a IXB part in FIG. 9A;

FIG. 10 is a diagram for illustrating a configuration of a cooling section to which the exemplary embodiment is applied;

FIGS. 11A and 11 are diagrams schematically showing a flow of a raw-material gas when the raw-material gas is supplied from the raw-material gas supply section to which the exemplary embodiment is applied;

FIG. 12 is a diagram schematically showing a flow of the raw-material gas and a blocking gas in a container chamber;

FIG. 13 is an enlarged view of a XIII part in FIG. 12; and

FIG. 14 is a XIV-XIV cross-sectional view in FIG. 12.

### DESCRIPTION OF EMBODIMENTS

Hereinafter, an exemplary embodiment according to the present invention will be described in detail with reference to attached drawings.

### Entire Configuration of CVD Device

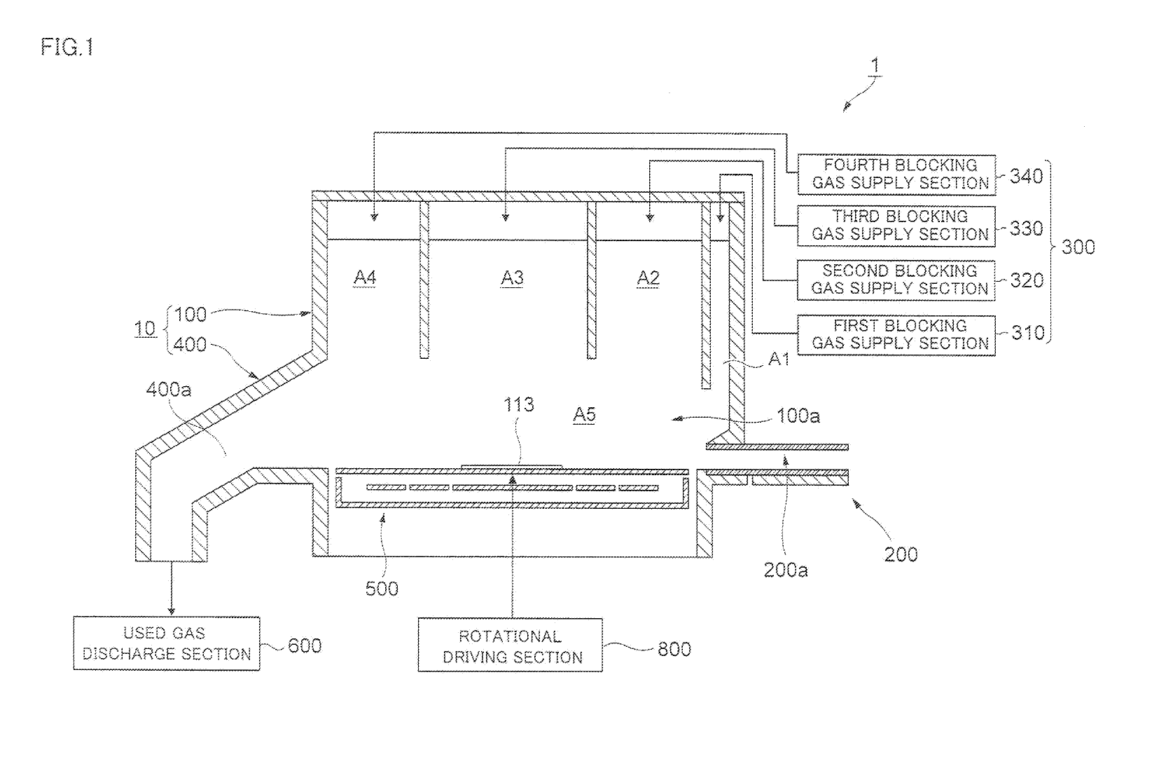

FIG. 1 is an entire configuration diagram of a CVD device 1 to which an exemplary embodiment is applied.

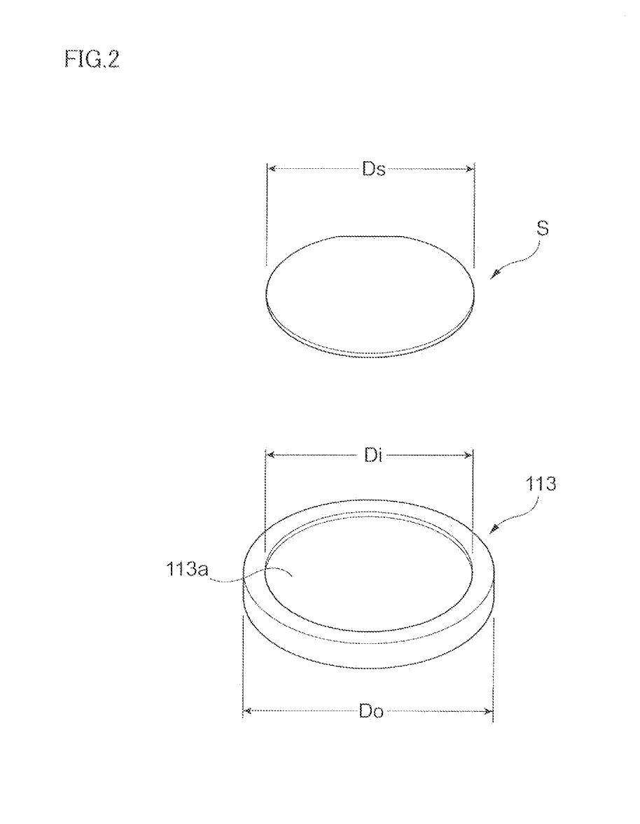

Moreover, FIG. 2 is a perspective view of a substrate S onto which a film is laminated and a loading body 113 on which the substrate S is loaded, which are used in the CVD device 1.

The CVD device 1 is an example of an SiC-film formation device, and is used for producing an SiC epitaxial wafer in which a 4H—SiC film is epitaxially grown on the substrate S configured with an SiC single crystals by a so-called thermal CVD method.

The CVD device 1 has a reaction container 10 including: a container chamber 100, in which vapor phase reaction for growing the film on the substrate S is performed, and which is provided with an interior space 100a for containing the substrate S loaded on the loading body 113; and a discharge duct 400, which is provided with a discharge space 400a communicated to the interior space 100a, for discharging gas inside the interior space 100a to the outside.

Moreover, in addition to the reaction container 10, the CVD device 1 further includes: a raw-material gas supply section 200 that supplies the interior space 100a of the container chamber 100 with a raw-material gas, which is a raw material for a film, via a supply space 200a; a blocking gas supply section 300 that assists in carrying the raw-material gas along the horizontal direction and supplies a blocking gas for blocking upward movement of the raw-material gas; a heating mechanism 500 as an example of a heating unit or a heater that heats the substrate S and surroundings thereof in the container chamber 100; a used gas discharge section 600 that discharges used gases (such as the raw-material gas (including a gas subjected to reaction), the blocking gas and the like) carried from the interior space 100a of the container chamber 100 to the outside via the discharge space 400a provided to the discharge duct 400; and a rotational driving section 800 that rotates the substrate S via the loading body 113 in the container chamber 100. It should be noted that the used gas discharge section 600 is also used in reducing pressure in the interior space 100a via the discharge space 400a.

Here, the loading body 113 has a disk shape, and at a center portion of the top surface thereof, a recessed portion 113a for placing the substrate S is provided. The loading body 113 is configured with graphite (carbon). The graphite may be coated with SiC, TaC or the like.

Moreover, as the substrate S, of the SiC single crystal having many polytypes, the one with any polytype may be used; however, in a case where the film to be formed on the substrate S is configured with 4H—SiC, it is desirable to use 4H—SiC as the substrate S. Here, as an off angle imparted to a crystal growth surface of the substrate S, any off angle may be imparted;

however, in terms of reduction of cost of producing the substrate S while ensuring step-flow growth of the SiC film, it is preferable to set the off angle of the order of 0.4° to 8°.

It should be noted that the substrate diameter Ds, which is the outer diameter of the substrate S, is able to be selected from various sizes, such as 2 inches, 3 inches, 4 inches, 6 inches or the like. At this time, the loading body inner diameter Di, which is the inner diameter of the recessed portion 113a in the loading body 113, is set slightly larger than the substrate diameter Ds, whereas, the loading body outer diameter Do, which is the outer diameter of the loading body 113, is set larger than the loading body inner diameter Di (Ds <Di<Do).

Moreover, as the raw-material gas to be supplied to the container chamber 100 by use of the raw-material gas supply section 200, it can be safely said that the gas is appropriately selected from gases capable of forming the SiC on the substrate S along the vapor phase reaction in the container chamber 100; however, usually, the silicon-containing gas that contains Si and the carbon-containing gas that contains C are used. It should be noted that, in this example, monosilane (SiH₄) gas and propane (C₃H₈) gas are used as the silicon-containing gas and the carbon-containing gas, respectively. Moreover, the raw-material gas of the exemplary embodiment contains hydrogen (H₂) gas as a carrier gas, in addition to the above-described monosilane gas and propane gas. It should be noted that the raw-material gas supply section 200 is able to supply the carrier gas only.

Further, as the blocking gas to be supplied to the container chamber 100 by use of the blocking gas supply section 300 as an example of a blocking gas supply unit or an inert gas supply section, it is desirable to use a gas less reactive to the above-described raw-material gas (a gas that is inactive for the raw-material gas). In this example, as the blocking gas, hydrogen gas is used.

It should be noted that in the case the SiC epitaxial film to be laminated on the substrate S is controlled to be a hole-conduction type (p-type) or an electron-conduction type (n-type), doping of a different element is performed when the SiC epitaxial film is laminated. Here, in the case where the SiC epitaxial film is controlled to be the p-type, it is desirable that the SiC epitaxial film is doped with aluminum (Al) as an acceptor. In this case, in the above-described raw-material gas, trimethyl aluminum (TMA) may further be contained. Moreover, in the case where the SiC epitaxial film is controlled to be the n-type, it is desirable that the SiC epitaxial film is doped with nitrogen as a donor. In this case, in the above-described raw-material gas or blocking gas, nitrogen (N₂) may further be contained.

### Configuration of Reaction Container

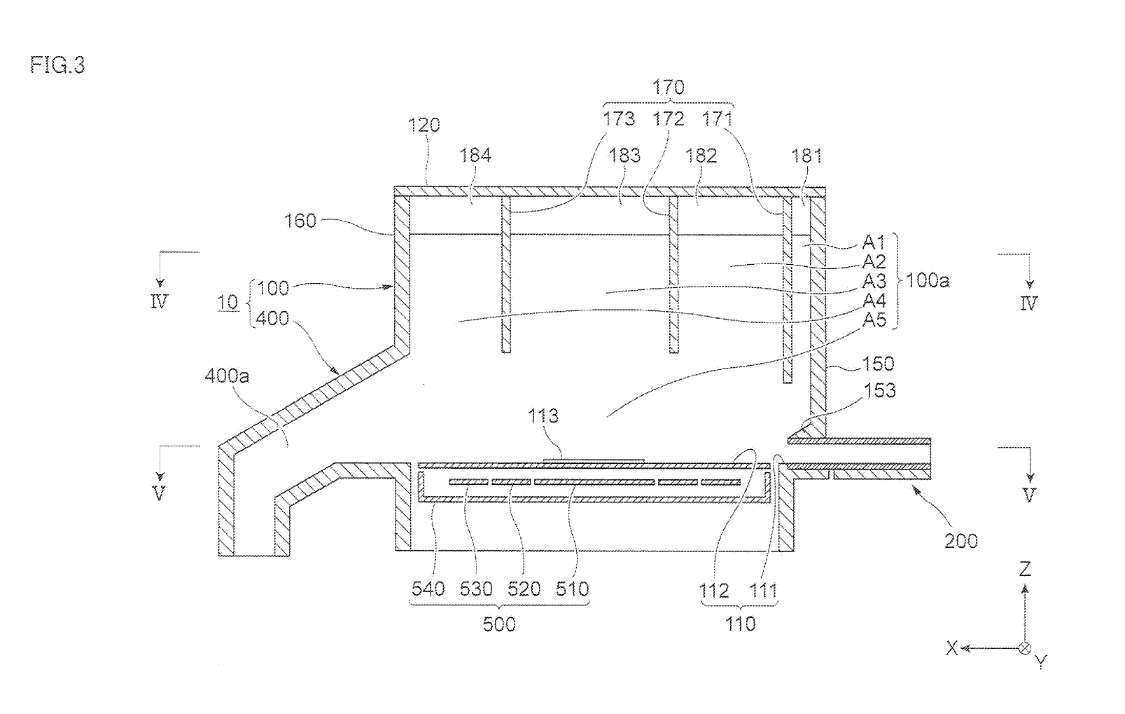

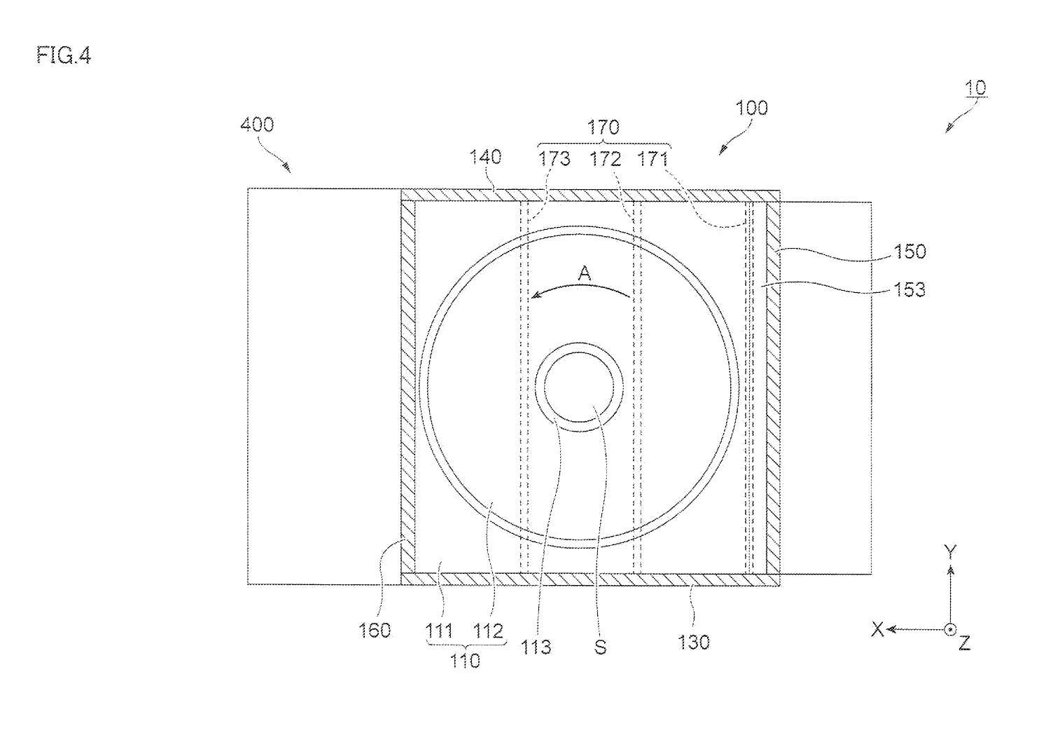

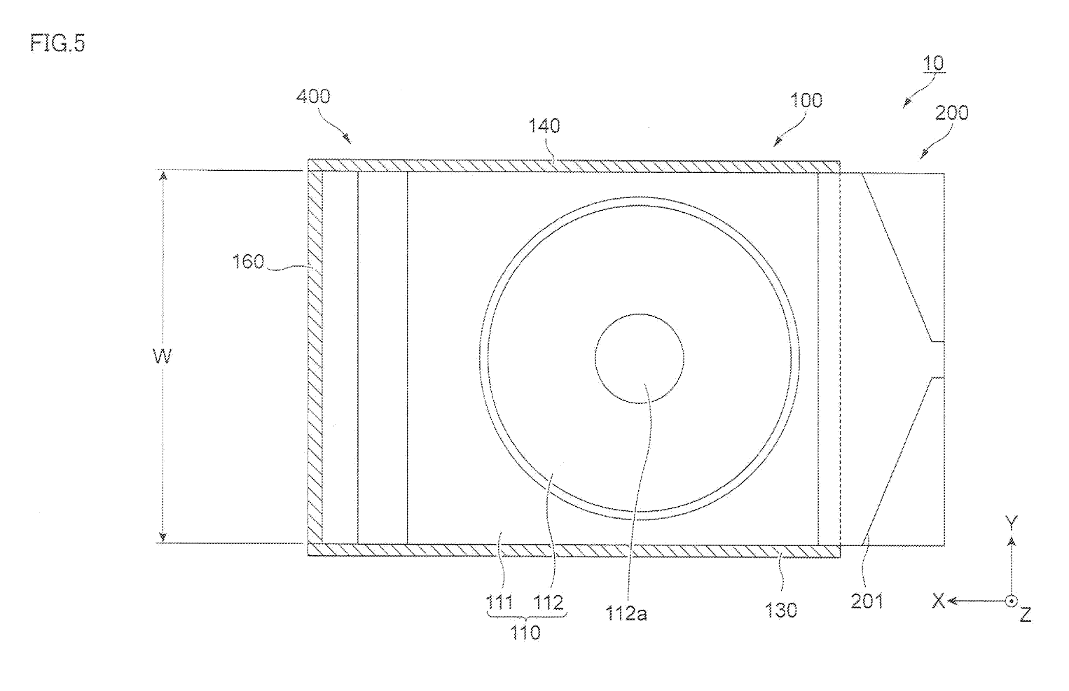

FIG. 3 is a virtual cross-sectional view of the reaction container 10 in the CVD device 1. Moreover, FIG. 4 is a IV-IV cross-sectional view in FIG. 3, and FIG. 5 is a V-V cross-sectional view in FIG. 3.

It should be noted that, in the following description, in FIG. 3, it is assumed that the direction heading from the right side toward the left side in the figure is an X-direction, the direction heading from the front side toward the rear side in the figure is a Y-direction, and the direction heading from the lower side toward the upper side in the figure is a Z-direction. Then, in this example, the Z-direction corresponds to the vertical direction, and the X-direction and the Y-direction correspond to the horizontal direction. Moreover, in the exemplary embodiment, the X-direction and the −Z-direction correspond to a first direction and a second direction, respectively.

The reaction container 10 includes: a floor section 110 provided along an XY plane on an upstream side in the Z-direction (a lower side) as viewed from the interior space 100a, on which the loading body 113 is arranged; a ceiling 120 provided along the XY plane on a downstream side in the Z-direction (an upper side) as viewed from the interior space 100a and facing the floor section 110; a first side wall 130 provided along an XZ plane on an upstream side in the Y-direction as viewed from the interior space 100a; a second side wall 140 provided along the XZ plane on a downstream side in the Y-direction as viewed from the interior space 100a and facing the first side wall 130; a third side wall 150 provided along a YZ plane on an upstream side in the X-direction as viewed from the interior space 100a; and a fourth side wall 160 provided along the YZ plane on a downstream side in the X-direction as viewed from the interior space 100a and facing the third side wall 150.

It should be noted that, in the following description, as shown in FIG.

5, in the container chamber 100 (the interior space 100a) of the reaction container 10, the length from the first side wall 130 to the second side wall 140 in the Y-direction is referred to as an interior width W.

The first side wall 130, the second side wall 140, the third side wall 150 and the fourth side wall 160 of the exemplary embodiment are configured by laminating stainless steel and TaC (tantalum carbide)-coated graphite so that the TaC-coated graphite faces the interior space 100a. It should be noted that the TaC-coated graphite means a base material made of graphite (carbon) on a surface (a side facing the interior space 100a) of which a coating layer made of TaC is provided. With such a configuration, in the first side wall 130, the second side wall 140, the third side wall 150 and the fourth side wall 160, stainless steel thereof is not exposed to the interior space 100a.

Moreover, at a lower end portion of the third side wall 150, a protruding member 153 that is arranged to protrude from the third side wall 150 toward the X-direction is provided. The protruding member 153 includes an inclined surface that is inclined in a lower left direction in FIG. 3, and a tip end (an end portion on the downstream side in the X-direction) of the protruding member 153 extends to a position directly below a first dividing member 171 to be described later. Moreover, the protruding member 153 is configured with the TaC-coated graphite.

Here, to an end portion of the third side wall 150 on the upstream side in the Z-direction (lower side), a raw-material gas supply duct 201 of the raw-material gas supply section 200 is connected.

Moreover, the floor section 110 is, after extending from the third side wall 150 along the X-direction, formed to be inclined obliquely downward along the X-direction and the −Z-direction in accordance with the discharge space 400a, and further, formed to be extended downward along the −Z-direction. On the other hand, the fourth side wall 160 is, after extending from the ceiling 120 along the −Z-direction, formed to be inclined obliquely downward along the X-direction and the −Z-direction in accordance with the discharge space 400a, and further, formed to be extended downward along the −Z-direction. Then, the first side wall 130 and the second side wall 140 are also extended in accordance with the discharge space 400a after the manner of the above-described floor section 110 and fourth side wall 160.

The floor section 110 is formed integrally with the first side wall 130, the second side wall 140 and the third side wall 150, and includes a fixing section 111 at a center portion of which a circular-shaped opening is formed, and a rotating table 112 that is arranged in the opening provided in the fixing section 111, to which the loading body 113 placing the substrate S is attached, and is rotationally driven in the direction of arrow A by the rotational driving section 800 (refer to FIG. 1).

The fixing section 111 that constitutes the floor section 110 is configured by laminating stainless steel and TaC (tantalum carbide)-coated graphite so that the TaC-coated graphite faces the interior space 100a. With such a configuration, in the fixing section 111, stainless steel thereof is not exposed to the interior space 100a and the discharge space 400a.

Moreover, the rotating table 112 that constitutes the floor section 110 is arranged to be exposed to the interior space 100a and is configured with the TaC-coated graphite. Moreover, at a center portion of the top surface of the rotating table 112, a receiving section 112a (a recessed portion) for attaching the loading body 113 is formed.

The ceiling 120 is configured with a plate material made of stainless steel, and stainless steel is exposed to the interior space 100a. Moreover, to the ceiling 120, a flow-adjusting section 170 configured with plural plate-like members to adjust the flow of various kinds of gases in the interior space 100a.

It should be noted that the structures configured with the TaC-coated graphite in this example, such as the surfaces of the above-described first side wall 130 to fourth side wall 160 and the protruding member 153, are able to be configured with, for example, a carbon-based material or a metal material provided with a thermal insulation function and heat resistance for at least 600° C.

The flow-adjusting section 170 of the exemplary embodiment includes a first dividing member 171, a second dividing member 172 and a third dividing member 173, each of which is configured with a plate-like member made of stainless steel to divide the interior space 100a into plural regions. Here, in each of the first dividing member 171 to the third dividing member 173, an end portion on the upper side thereof is attached to the ceiling 120 and extends along the -Z-direction, and an end portion on the lower side thereof is positioned within the interior space 100a. Moreover, the length of the first dividing member 171, the second dividing member 172 and the third dividing member 173 in the Y-direction is set at the above-described interior width W. Accordingly, when the CVD device 1 is configured, an end face of the first dividing member 171 on the upstream side in the Y-direction is in contact with the first side wall 130, whereas, an end face of the first dividing member 171 on the downstream side in the Y-direction is in contact with the second side wall 140.

Further, the first dividing member 171, the second dividing member 172 and the third dividing member 173 are arranged in this order along the X-direction. Then, the first dividing member 171 is arranged at a position facing the third side wall 150, the third dividing member 173 is arranged at a position facing the fourth side wall 160, and the second dividing member 172 is arranged at a position between the first dividing member 171 and the third dividing member 173.

It should be noted that it may be possible for the CVD device 1 (refer to FIG. 1) to further include a cooling mechanism for cooling the first dividing member 171, the second dividing member 172 and the third dividing member 173. As a method of cooling the first dividing member 171 to the third dividing member 173, for example, a method such as a water-cooling method that runs cooling water inside the first dividing member 171 to the third dividing member 173 can be provided.

In the interior space 100a in the container chamber 100, the first dividing member 171 to the third dividing member 173 are arranged to avoid positions immediately above the loading body 113 put on the rotating table 112 of the floor section 110 and the substrate S loaded on the loading body 113. More specifically, in the exemplary embodiment, the loading body 113 is arranged at a portion between a position immediately below the second dividing member 172 and a position immediately below the third dividing member 173.

Then, in the exemplary embodiment, by attaching the first dividing member 171 to the third dividing member 173 to the interior space 100a, the interior space 100a is divided into 5 regions, more specifically, a first region A1, a second region A2, a third region A3, a fourth region A4 and a fifth region A5.

Of these, the first region A1 refers to a region, of the interior space 100a, surrounded by the ceiling 120, the first side wall 130, the second side wall 140, the third side wall 150 and the first dividing member 171.

Moreover, the second region A2 refers to a region, of the interior space 100a, surrounded by the ceiling 120, the first side wall 130, the second side wall 140, the first dividing member 171 and the second dividing member 172.

Further, the third region A3 refers to a region, of the interior space 100a, surrounded by the ceiling 120, the first side wall 130, the second side wall 140, the second dividing member 172 and the third dividing member 173. Still further, the fourth region A4 refers to a region, of the interior space 100a, surrounded by the ceiling 120, the first side wall 130, the second side wall 140, the third dividing member 173 and the fourth side wall 160.

Then, the fifth region A5 refers to a region, of the interior space 100a, on the floor section 110 side that is not included in the above-described first region A1 to fourth region A4.

In the exemplary embodiment, on the downstream side of the fifth region A5 in the Z-direction (the upper side), the first region A1, the second region A2, the third region A3 and the fourth region A4 are arranged along the X-direction in this order. Then, the fifth region A5 is individually communicated with each of the first region A1 to the fourth region A4. Moreover, the fifth region A5 is connected to the raw-material gas supply duct 201 of the raw-material gas supply section 200 on the upstream side of the fifth region A5 in the X-direction, and is communicated with the discharge space 400a on the downstream side of the fifth region A5 in the X-direction.

Then, the blocking gas supply section 300 of the exemplary embodiment includes, as shown in FIG. 1, via through holes (not shown) provided in the ceiling 120: a first blocking gas supply section 310 that supplies the inside of the first region A1 with a blocking gas (a first blocking gas) from above; a second blocking gas supply section 320 that supplies the inside of the second region A2 with a blocking gas (a second blocking gas) from above; a third blocking gas supply section 330 that supplies the inside of the third region A3 with a blocking gas (a third blocking gas) from above; and a fourth blocking gas supply section 340 that supplies the inside of the fourth region A4 with a blocking gas (a fourth blocking gas) from above. It should be noted that the blocking gas supply section 300 (the first blocking gas supply section 310 to the fourth blocking gas supply section 340) of the exemplary embodiment supplies the interior space 100a with the blocking gas (the first blocking gas to the fourth blocking gas) as-is without especially conducting preheating.

Moreover, the heating mechanism 500 as an example of the heating unit is, as shown in FIG. 3, provided below the rotating table 112 in the floor section 110. The heating mechanism 500 includes: a first heater 510 arranged below the loading body 113 attached onto the rotating table 112; a second heater 520 arranged outside of a peripheral edge of the first heater 510; a third heater 530 arranged outside of a peripheral edge of the second heater 520; and a reflective member 540 provided below the first heater 510 to the third heater 530 to reflect heat generated downward from the first heater 510 to the third heater 530 toward the rotating table 112 side. These first heater 510 to third heater 530 are configured with, for example, graphite (carbon), and are heaters of the self-heating type that evolves heat by itself by a current supplied from a not-shown power supply. Moreover, in the exemplary embodiment, the reflective member 540 is also configured with graphite (carbon).

Accordingly, in the exemplary embodiment, when the SiC film is formed on the substrate S, the substrate S is heated from the direction opposite to the SiC-film formation surface.

It should be noted that, in the CVD device 1 of the exemplary embodiment, a purge gas constituted by argon (Ar) gas is supplied toward the interior space 100a from beneath the rotating table 112 and the heating mechanism 500, to thereby suppress flow of the raw-material gas or the like into the heating mechanism 500 side from the interior space 100a via a gap between the fixing section 111 and the rotating table 112. It should be noted that the reason why argon gas is used as the purge gas is that, in a case where hydrogen gas is used as the purge gas, a heating efficiency of the substrate S by the heating mechanism 500 is reduced.

Then, the reaction chamber 10 further includes: a first blocking gas diffusing member 181 that is provided on the downstream side (the upper side) of the first region A1 in the Z-direction to face the ceiling 120, and lowers the first blocking gas, which has been supplied from the first blocking gas supply section 310 to the inside of the first region A1 along the -Z-direction, while diffusing thereof in the horizontal direction (the X-direction and the Y-direction); a second blocking gas diffusing member 182 that is provided on the downstream side of the second region A2 in the Z-direction to face the ceiling 120, and lowers the second blocking gas, which has been supplied from the second blocking gas supply section 320 to the inside of the second region A2 along the -Z-direction, while diffusing thereof in the horizontal direction; a third blocking gas diffusing member 183 that is provided on the downstream side of the third region A3 in the Z-direction to face the ceiling 120, and lowers the third blocking gas, which has been supplied from the third blocking gas supply section 330 to the inside of the third region A3 along the -Z-direction, while diffusing thereof in the horizontal direction; and a fourth blocking gas diffusing member 184 that is provided on the downstream side of the fourth region A4 in the Z-direction to face the ceiling 120, and lowers the fourth blocking gas, which has been supplied from the fourth blocking gas supply section 340 to the inside of the fourth region A4 along the −Z-direction, while diffusing thereof in the horizontal direction. Here, the first blocking gas diffusing member 181 is configured by stacking plural (in this example, five) rectangular-shaped plate members, in each of which plural holes are formed along the XY plane, in the Z-direction. Moreover, the second blocking gas diffusing member 182 to the fourth blocking gas diffusing member 184 have configurations in common with that of the first blocking gas 181.

### Dimension of Reaction Container

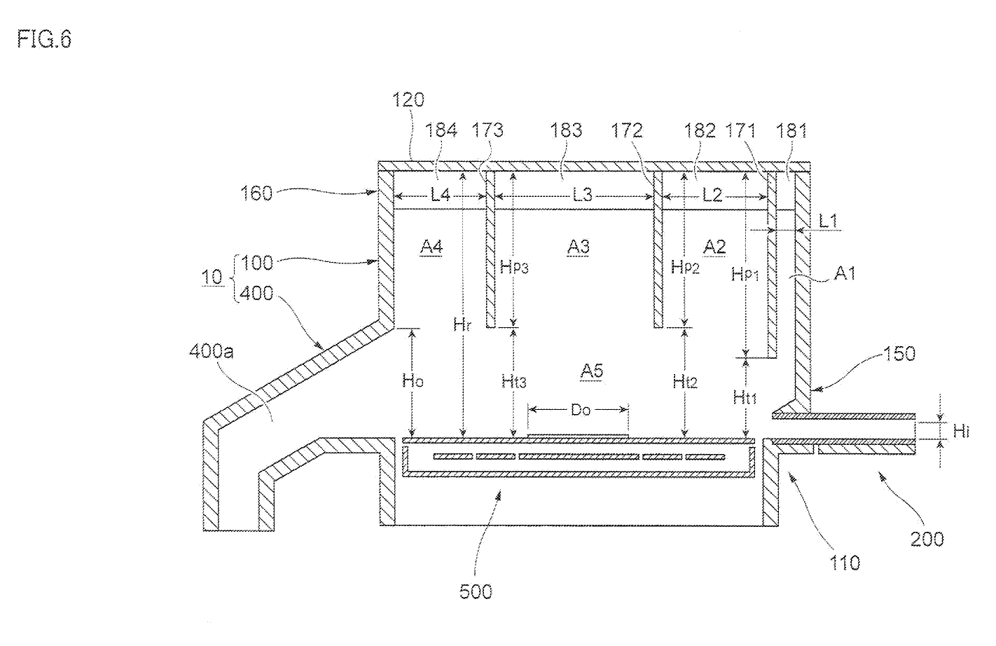

FIG. 6 is a diagram for illustrating various dimensions in the reaction container 10. First, in the container chamber 100 of the reaction container 10 (the interior space 100a, refer to FIG. 1), the distance from floor section 110 to the ceiling 120 in the Z-direction is assumed to be an interior height Hr. Moreover, it is assumed that the length of the first dividing member 171 in the Z-direction is a first dividing height Hp1, the length of the second dividing member 172 in the Z-direction is a second dividing height Hp2 and the length of the third dividing member 173 in the Z-direction is a third dividing height Hp3. Further, it is assumed that the distance from the floor section 110 to the lower end of the first dividing member 171 is a first space height Ht1, the distance from the floor section 110 to the lower end of the second dividing member 172 is a second space height Ht2 and the distance from the floor section 110 to the lower end of the third dividing member 173 is a third space height Ht3. At this time, Hr=Hp1+Ht1=Hp2+Ht2=Hp3+Ht3 holds.

Moreover, the distance in the Z-direction in an outlet of the supply space 200a (a communicating portion with the interior space 100a, refer to FIG. 1) is assumed to be a supply port height Hi, and the distance in the Z-direction in an inlet of the discharge space 400a (a communicating portion with the interior space 100a) is assumed to be a discharge port height Ho.

Further, it is assumed that the length of the first region A1 in the X-direction is a first region length L1, the length of the second region A2 in the X-direction is a second region length L2, the length of the third region A3 in the X-direction is a third region length L3 and the length of the fourth region A4 in the X-direction is a fourth region length L4.

It should be noted that the length of each of the first region A1 to the fifth region A5 in the Y-direction is, as described above, the common interior width W (refer to FIG. 5).

In the exemplary embodiment, the first dividing height Hp1, the second dividing height Hp2 and the third dividing height Hp3 have the relation specified by the expression Hp1>Hp2=Hp3. Then, the interior height Hr and each of these first dividing height Hp1 to third dividing height Hp3 have the relation specified by the expression Hp1≧Hr/2, Hp2≧Hr/2 and Hp3≧Hr/2. Here, since each of the interior height Hr and the first dividing height Hp1 to the third dividing height Hp3 regards the ceiling 120 as an upper end reference position, the lower end of each of the first dividing member 171 to the third dividing member 173 is positioned closer to the floor section 110 than the ceiling 120.

Moreover, the supply port height Hi, the first interior height Ht1 to the third interior height Ht3 and the discharge port height Ho have the relation specified by the expression Hi<Ht1<Ht2=Ht3=Ho. Here, since each of the supply port height Hi, the first interior height Ht1 to the third interior height Ht3 and the discharge port height Ho regards the floor section 110 as a lower end reference position, the upper end of the discharge port Ho exists at a position higher than the upper end of the supply port Hi.

Further, the first region length L1 to the fourth region length L4 have the relation specified by the expression L1<L4<L2<L3. Then, the first region length L1 is, as compared with the second region length L2 to the fourth region length L4, for example, set to one quarter or less.

Still further, the loading body outer diameter Do of the loading body 113 to load the substrate S and the third region length L3 of the third region length A3 positioned immediately above the loading body 113 have the relation specified by the expression Do<L3. Here, since the loading body outer diameter Do and the substrate diameter Ds of the substrate S have the relation specified by the expression Ds<Do (refer to FIG. 2), the third region length L3 and the substrate diameter Ds have the relation specified by the expression Ds<L3.

### Configuration of Raw-Material Gas Supply Section

Subsequently, the raw-material gas supply section 200 in the CVD device 1 of the exemplary embodiment will be described.

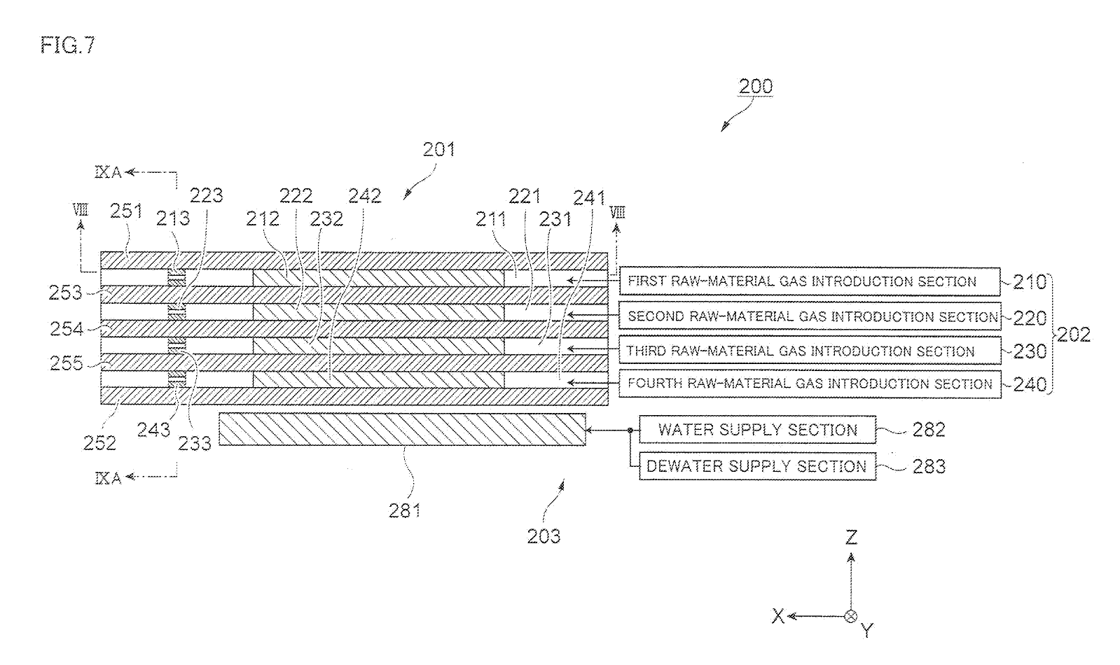

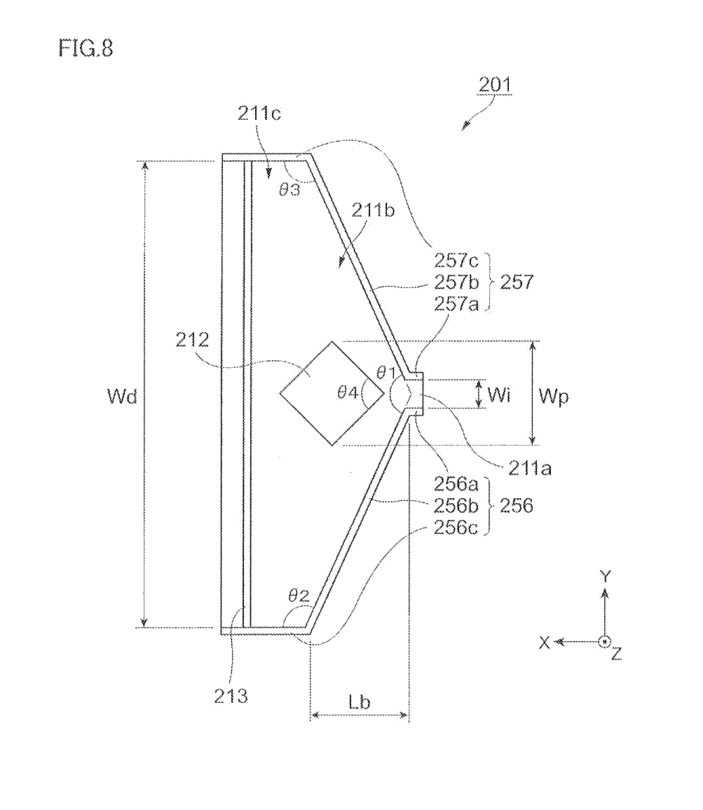

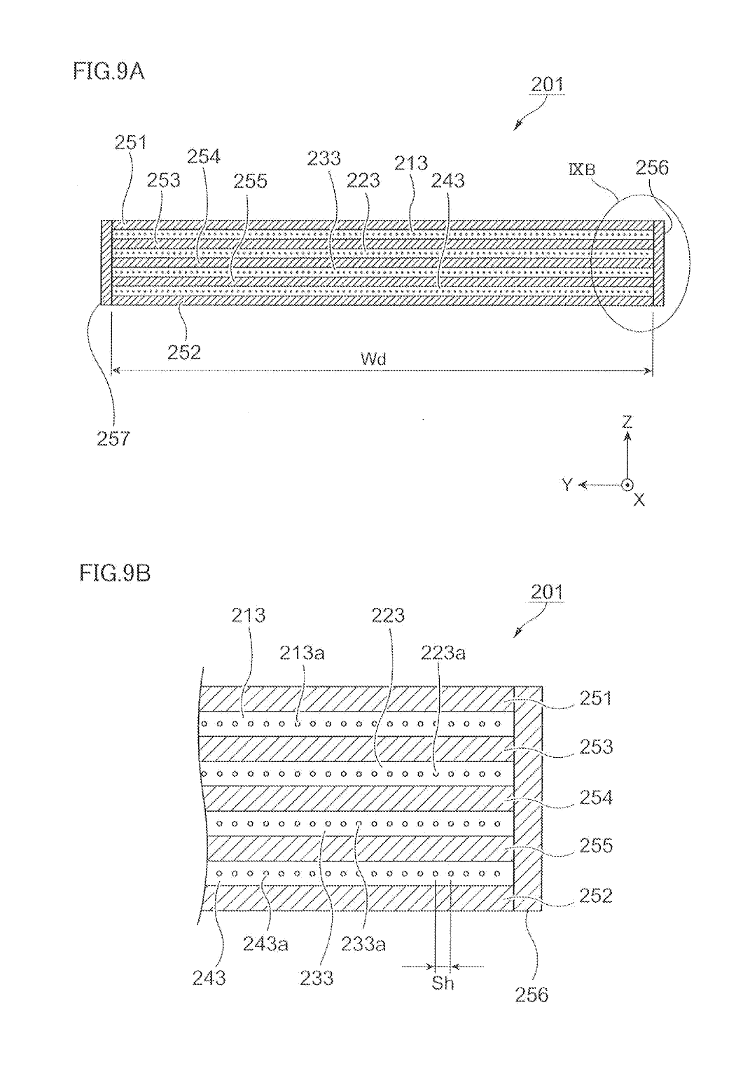

FIG. 7 is a virtual cross-sectional view of the raw-material gas supply section 200 to which the exemplary embodiment is applied. Moreover, FIG. 8 is an VIII-VIII cross-sectional view in FIG. 7. Further, FIG. 9A is a IXA-IXA cross-sectional view in FIG. 7, and FIG. 9B is an enlarged view of a IXB part in FIG. 9A.

The raw-material gas supply section 200 of the exemplary embodiment includes: the raw-material gas supply duct 201 that supplies the interior space 100a of the container chamber 100 with the raw-material gas; a raw-material gas introduction section 202 that introduces the raw-material gas to the raw-material gas supply duct 201; and a cooling section 203 as an example of the cooling unit that cools the raw-material gas moving inside the raw-material gas supply duct 201.

Here, in the raw-material gas supply section 200 of the exemplary embodiment, four spaces for supplying the interior space 100a with the raw-material gas are provided in line along the −Z-direction. Specifically, in the raw-material gas supply duct 201 of the raw-material gas supply section 200, there are provided a first supply space 211 for supplying the interior space 100a with a first raw-material gas, a second supply space 221 for supplying the interior space 100a with a second raw-material gas, a third supply space 231 for supplying the interior space 100a with a third raw-material gas and a fourth supply space 241 for supplying the interior space 100a with a first raw-material gas in order in line in the −Z-direction. Then, in the state where the raw-material gas supply duct 201 is attached to the reaction container 10 (the container chamber 100), each of the first supply space 211, the second supply space 221, the third supply space 231 and the fourth supply space 241 is communicated with the interior space 100a of the container chamber 100.

Moreover, the raw-material gas introduction section 202 includes: a first raw-material gas introduction section 210 that introduces the first raw-material gas to the first supply space 211 in the raw-material gas supply duct 201 from the upstream side in the X-direction; a second raw-material gas introduction section 220 that introduces the second raw-material gas to the second supply space 221 from the upstream side in the X-direction; a third raw-material gas introduction section 230 that introduces the third raw-material gas to the third supply space 231 from the upstream side in the X-direction; and a fourth raw-material gas introduction section 240 that introduces the fourth raw-material gas to the fourth supply space 241 from the upstream side in the X-direction.

In the exemplary embodiment, the first raw-material gas introduction section 210 introduces hydrogen gas, which is a carrier gas, to the first supply space 211 as the first raw-material gas.

The second raw-material gas introduction section 220 introduces a mixed gas of monosilane gas, which is the silicon-containing gas, and hydrogen gas, which is the carrier gas, to the second supply space 221 as the second raw-material gas.

The third raw-material gas introduction section 230 introduces a mixed gas of propane gas, which is the carbon-containing gas, and hydrogen gas, which is the carrier gas, to the third supply space 231 as the third raw-material gas.

The fourth raw-material gas introduction section 240 introduces hydrogen gas, which is the carrier gas, to the fourth supply space 241 as the fourth raw-material gas.

It should be noted that, in the exemplary embodiment, the first raw-material gas corresponds to a first assist gas (an assist gas), the second raw-material gas corresponds to a silicon raw-material gas, the third raw-material gas corresponds to a carbon raw-material gas, and the fourth raw-material gas corresponds to a second assist gas (an assist gas).

Moreover, in the exemplary embodiment, the first supply space 211 corresponds to a first assist gas supply route and an assist gas supply unit, the second supply space 221 corresponds to a silicon raw-material gas supply route and a silicon raw-material gas supply unit, the third supply space 231 corresponds to a carbon raw-material gas supply route and a carbon raw-material gas supply unit, and the fourth supply space 241 corresponds to a second assist gas supply route and the assist gas supply unit.

### Configuration of Raw-Material Gas Supply Duct 201

Subsequently, a configuration of the raw-material gas supply duct 201 will be described in detail.

The raw-material gas supply duct 201 includes: a duct upper wall 251 provided along the XY plane on the downstream side in the Z-direction (the upper side) as viewed from the first supply space 211 to the fourth supply space 214; a duct lower wall 252 provided along the XY plane on the upstream side in the Z-direction (lower side) as viewed from the first supply space 211 to the fourth supply space 214, to face the duct upper wall 251 through later-described first duct dividing wall 253, second duct dividing wall 254, third duct dividing wall 255 and the first supply space 211 to the fourth supply space 214; a first duct side wall 256 provided along the Z-direction on the upstream side in the Y-direction as viewed from the first supply space 211 to the fourth supply space 214; and a second duct side wall 257 provided along the Z-direction on the downstream side in the Y-direction as viewed from the first supply space 211 to the fourth supply space 214, to face the first duct side wall 256 through the first duct dividing wall 253, the second duct dividing wall 254 and the third duct dividing wall 255.

Further, the raw-material gas supply duct 201 includes the first duct dividing wall 253, the second duct dividing wall 254 and the third duct dividing wall 255 arranged in order in the −Z-direction, each of which is provided along the XY plane between the duct upper wall 251 and the duct lower wall 252.

The first duct dividing wall 253, the second duct dividing wall 254 and the third duct dividing wall 255 divide the space surrounded by the duct upper wall 251, the duct lower wall 252, the first duct side wall 256 and the second duct side wall 257, to thereby divide the space into the first supply space 211, the second supply space 221, the third supply space 231 and the fourth supply space 241.

To put another way, the first supply space 211 is formed by being surrounded by the duct upper wall 251, the first duct dividing wall 253, the first duct side wall 256 and the second duct side wall 257, the second supply space 221 is formed by being surrounded by the first duct dividing wall 253, the second duct dividing wall 254, the first duct side wall 256 and the second duct side wall 257, the third supply space 231 is formed by being surrounded by the second duct dividing wall 254, the third duct dividing wall 255, the first duct side wall 256 and the second duct side wall 257, and the fourth supply space 241 is formed by being surrounded by the third duct dividing wall 255, the duct lower wall 252, the first duct side wall 256 and the second duct side wall 257.

Here, each of the duct upper wall 251, the duct lower wall 252, the first duct side wall 256 and the second duct side wall 257 of the exemplary embodiment is configured with a plate material made of stainless steel. In the same manner, each of the first duct dividing wall 253, the second duct dividing wall 254 and the third duct dividing wall 255 is configured with the plate material made of stainless steel. Accordingly, stainless steel is exposed to the first supply space 211, the second supply space 221, the third supply space 231 and the fourth supply space 241.

In the raw-material gas supply duct 201 of the exemplary embodiment, in the first supply space 211, a first diffusion plate 212 for diffusing the first raw-material gas introduced from the first raw-material gas introduction section 210 is provided. Further, in the first supply space 211, on the downstream side of the first diffusion plate 212 in the X-direction, a first flow-adjusting member 213 for adjusting flow of the first raw-material gas diffused by the first diffusion plate 212 is provided.

In the same manner, in the second supply space 221, a second diffusion plate 222 for diffusing the second raw-material gas introduced from the second raw-material gas introduction section 220 is provided, and on the downstream side of the second diffusion plate 222 in the X-direction, a second flow-adjusting member 223 for adjusting the flow of the second raw-material gas diffused by the second diffusion plate 222 is provided.

Further, in the third supply space 231, a third diffusion plate 232 for diffusing the third raw-material gas introduced from the third raw-material gas introduction section 230 is provided, and on the downstream side of the third diffusion plate 232 in the X-direction, a third flow-adjusting member 233 for adjusting the flow of the third raw-material gas diffused by the third diffusion plate 232 is provided.

Still further, in the fourth supply space 241, a fourth diffusion plate 242 for diffusing the fourth raw-material gas introduced from the fourth raw-material gas introduction section 240 is provided, and on the downstream side of the fourth diffusion plate 242 in the X-direction, a fourth flow-adjusting member 243 for adjusting the flow of the fourth raw-material gas diffused by the fourth diffusion plate 242 is provided.

The first duct side wall 256 of the exemplary embodiment includes: a first upstream section 256a formed from an end portion on the upstream side in the X-direction along the XZ plane; a first middle section 256b extended from a downstream end in the X-direction of the first upstream section 256a; and a first downstream section 256c extended from a downstream end in the X-direction of the first middle section 256b and formed along the XZ plane.

In the same manner, the second duct side wall 257 includes: a second upstream section 257a formed from an end portion on the upstream side in the X-direction along the XZ plane; a second middle section 257b extended from a downstream end in the X-direction of the second upstream section 257a; and a second downstream section 257c extended from a downstream end in the X-direction of the second middle section 257b and formed along the XZ plane.

The first middle section 256b of the first duct side wall 256 is formed along the Z-direction and inclined obliquely along the X-direction and the −Y-direction as viewed from the Z-direction. Moreover, the second middle section 257b of the second duct side wall 257 is formed along the Z-direction and inclined obliquely along the X-direction and the Y-direction as viewed from the Z-direction.

Accordingly, in a case where the raw-material gas supply duct 201 is viewed from the Z-direction, the first middle section 256b of the first duct side wall 256 and the second middle section 257b of the second duct side wall 257 are configured to be separated from each other along with movement toward the downstream side in the X-direction.

Then, in the case of being viewed from the Z-direction, assuming that an angle formed by the first middle section 256b of the first duct side wall 256 and the second middle section 257b of the second duct side wall 257 is a first duct angle θ1, the first duct angle θ1 is an obtuse angle (θ1>90°).

Moreover, in the raw-material gas supply duct 201 of the exemplary embodiment, the first upstream section 256a of the first duct side wall 256 and the second upstream section 257a of the second duct side wall 257 are formed to be in parallel with each other. In the same manner, the first downstream section 256c of the first duct side wall 256 and the second downstream section 257c of the second duct side wall 257 are formed to be in parallel with each other.

Then, in the exemplary embodiment, in a case where the raw-material gas supply duct 201 is viewed from the Z-direction, on the assumption that an angle formed by the first middle section 256b and the first downstream section 256c of the first duct side wall 256 is a second duct angle θ2, the second duct angle θ2 is an obtuse angle (θ2>90°). In the same manner, on the assumption that an angle formed by the second middle section 257b and the second downstream section 257c of the second duct side wall 257 is a third duct angle θ3, the third duct angle θ3 is an obtuse angle (θ3>90°). It should be noted that, in this example, the second duct angle θ2 and the third duct angle θ3 are equal (θ2=θ3).

Here, the first supply space 211, which is surrounded by the duct upper wall 251, the first duct dividing wall 253, the first duct side wall 256 and the second duct side wall 257, is separated into a first introduction region 211a into which the first raw-material gas is introduced from the first raw-material gas introduction section 210, a first diffusion region 211b in which the first raw-material gas moved from the first introduction region 211 a is diffused in the Y-direction and the −Y-direction, and a first discharge region 211c in which the first raw-material gas moved from the first diffusion region 211b is discharged toward the interior space 100a (refer to FIG. 1) of the container chamber 100 (refer to FIG. 1).

Here, the first introduction region 211a refers to, of the first supply space 211, a region surrounded by the duct upper wall 251, the first duct dividing wall 253, the first upstream section 256a in the first duct side wall 256 and the second upstream section 257a in the second duct side wall 257. Moreover, the first diffusion region 211b refers to, of the first supply space 211, a region surrounded by the duct upper wall 251, the first duct dividing wall 253, the first middle section 256b in the first duct side wall 256 and the second middle section 257b in the second duct side wall 257. Further, the first discharge region 211c refers to, of the first supply space 211, a region surrounded by the duct upper wall 251, the first duct dividing wall 253, the first downstream section 256c in the first duct side wall 256 and the second downstream section 257c in the second duct side wall 257.

It should be noted that the above-described first diffusion plate 212 is formed to extend, of the first supply space 211, over the first diffusion region 211b and the first discharge region 211c. Moreover, the first flow-adjusting member 213 is formed, of the first supply space 211, in the first discharge region 211c.

If it is assumed that a width of the first discharge region 211c along the Y-direction (in other words, a distance between the first downstream section 256c and the second downstream section 257c) is a discharge width Wd, in the exemplary embodiment, the discharge width Wd is equal to the above-described interior width W (Wd=W).

Moreover, if it is assumed that a width of the first introduction region 211a along the Y-direction (in other words, a distance between the first upstream section 256a and the second upstream section 257a) is an introduction width Wi, the introduction width Wi is narrower than the discharge width Wd (the interior width W) (Wi<Wd).

Then, a width of the first diffusion region 211b along the Y-direction (in other words, a distance between the first middle section 256b and the second middle section 257b) is formed to continuously extend from the introduction width Wi toward the discharge width Wd (the interior width W) along with movement from the upstream side in the X-direction toward the downstream side in the X-direction.

Moreover, if it is assumed that a length of the first diffusion region 211b along the X-direction is a diffusion length Lb, in the exemplary embodiment, the discharge width Wd is larger than twice as long as the diffusion length Lb (Wd>2Lb).

Here, in the exemplary embodiment, in the case where, as described above, the discharge width Wd is set constant by causing the first duct angle θ1 to be the obtuse angle, it becomes possible to reduce the diffusion length Lb of the first diffusion region 211b, as compared to a case where the first duct angle θ1 is an acute angle. As a result of this, as compared to a case where the present configuration is not employed, it becomes possible to reduce the length in the X-direction of the raw-material gas supply duct 201, and accordingly, it becomes possible to downsize the CVD device 1 (refer to FIG. 1).

It should be noted that, though detailed description is omitted, since the first duct side surface 256 and the second duct side surface 257 have the configuration as described above, the second supply space 221, the third supply space 231 and the fourth supply space 241 have the configuration similar to that of the first supply space 211. In other words, each of the second supply space 221 to the fourth supply space 241 includes: an introduction region (not shown) to which each of the second raw-material gas to the fourth raw-material gas is introduced from the raw-material gas introduction section 202; a diffusion region (not shown) in which each of the second raw-material gas to the fourth raw-material gas moved from the introduction region is diffused in the Y-direction and in the −Y-direction; and a discharge region in which each of the second raw-material gas to the fourth raw-material gas moved from the diffusion region is discharged toward the interior space 100a (refer to FIG. 1) of the container chamber 100 (refer to FIG. 1).

### Configuration of Diffusion Plate

Subsequently, a configuration of the first diffusion plate 212 provided in the first supply space 211 will be described.

The first diffusion plate 212 is formed to extend over the first diffusion region 211b and the first discharge region 211c of the first supply space 211, and is arranged at a center portion in the Y-direction of the first diffusion region 211b and the first discharge region 211c.

The first diffusion plate 212 of the exemplary embodiment is configured with a plate-like member having a square shape as viewed from the Z-direction, and is arranged so that two diagonal lines of the square are along the X-direction and the Y-direction, respectively. Accordingly, one of corners of the first diffusion plate 212 showing the square shape faces the first introduction region 211a side.

Then, if it is assumed that the angle in the first diffusion plate 212 that faces the first introduction region 211a side (the upstream side in the X-direction) is a diffusion plate angle θ4 (=90°), θ4 is smaller than the first duct angle θ1 (θ4<θ1).

Moreover, if it is assumed that a width of the first diffusion plate 212 in the Y-direction is a diffusion plate width Wp, the diffusion plate width Wp is set larger than the introduction width Wi and smaller than the discharge width Wd (the interior width W) (Wi<Wp<W). It should be noted that a ratio between the diffusion plate width Wp and the discharge width Wd (the interior width W) is preferably in the range of 0.2 to 0.6, and more preferably, in the range of 0.3 to 0.4.

It should be noted that the diffusion plate width Wp in the first diffusion plate 212 of the exemplary embodiment is the length of the diagonal line, which is along the Y-direction, in the first diffusion plate 212 having a square shape, and the diagonal line in the first diffusion plate along the Y-direction is positioned in the first diffusion region 211b in the first supply space 211.

Further, a thickness of the first diffusion plate 212 in the Z-direction is set substantially the same as the distance between the duct upper wall 251 and the first duct dividing wall 253 in the Z-direction. In other words, the first raw-material gas introduced into the first supply space 211 is not able to move from a region where the first diffusion plate 212 in the first supply space.

The first diffusion plate 212 of the exemplary embodiment is formed of stainless steel. Moreover, the first diffusion plate 212 is configured to be capable of being attached or detached, and accordingly, when the raw-material gas supply duct 201 is assembled, it is possible to be attached or detached, as needed.

It should be noted that, though detailed description is omitted, the second diffusion plate 222, the third diffusion plate 232 and the fourth diffusion plate 242 have the configuration similar to that of the first diffusion plate 212.

### Configuration of Flow-Adjusting Member

Subsequently, a configuration of the first flow-adjusting member 213 provided to the first supply space 211 will be described.

The first flow-adjusting member 213 of the exemplary embodiment is configured with a plate-like member and formed along the YZ plane in the first discharge region 211c in the first supply space 211.

The height of the first flow-adjusting member 213 along the Z-direction is configured substantially the same as the distance between the duct upper wall 251 and the first duct dividing wall 253. Further, a width of the first flow-adjusting member 213 along the Y-direction is configured substantially the same as the above-described discharge width Wd (the interior width W).

Moreover, in the first flow-adjusting member 213, plural first through holes 213a penetrating through in the X-direction are formed in line at constant intervals along the Y-direction.

Accordingly, the first discharge region 211c is divided by the first flow-adjusting member 213 into the upstream side in the X-direction and the downstream side in the X-direction, and via the plural first through holes 213a formed in the first flow-adjusting member 213, the upstream side in the X-direction and the downstream side in the X-direction of the first discharge region 211c are communicated with each other.

The diameter of each of the first through holes 213a is 0.2 mm to 2 mm, and preferably, 0.3 mm to 1 mm, and the interval Sh between the adjacent first through holes 213a is 0.5 mm to 5 mm, and preferably, 1 mm to 3 mm. It should be noted that the diameter and the interval Sh of the first through holes 213a are not limited thereto, and it is possible to be changed.

Moreover, the first flow-adjusting member 213 of the exemplary embodiment is configured with, for example, stainless steel.

It should be noted that, though detailed description is omitted, the second flow-adjusting member 223, the third flow-adjusting member 233 and the fourth flow-adjusting member 243 have the configuration similar to that of the first flow-adjusting member 213, and as shown in FIG. 9B, plural second through holes 223a are formed in the second flow-adjusting member 223, plural third through holes 233a are formed in the third flow-adjusting member 233, and plural fourth through holes 243a are formed in the fourth flow-adjusting member 243.

### Configuration of Cooling Section

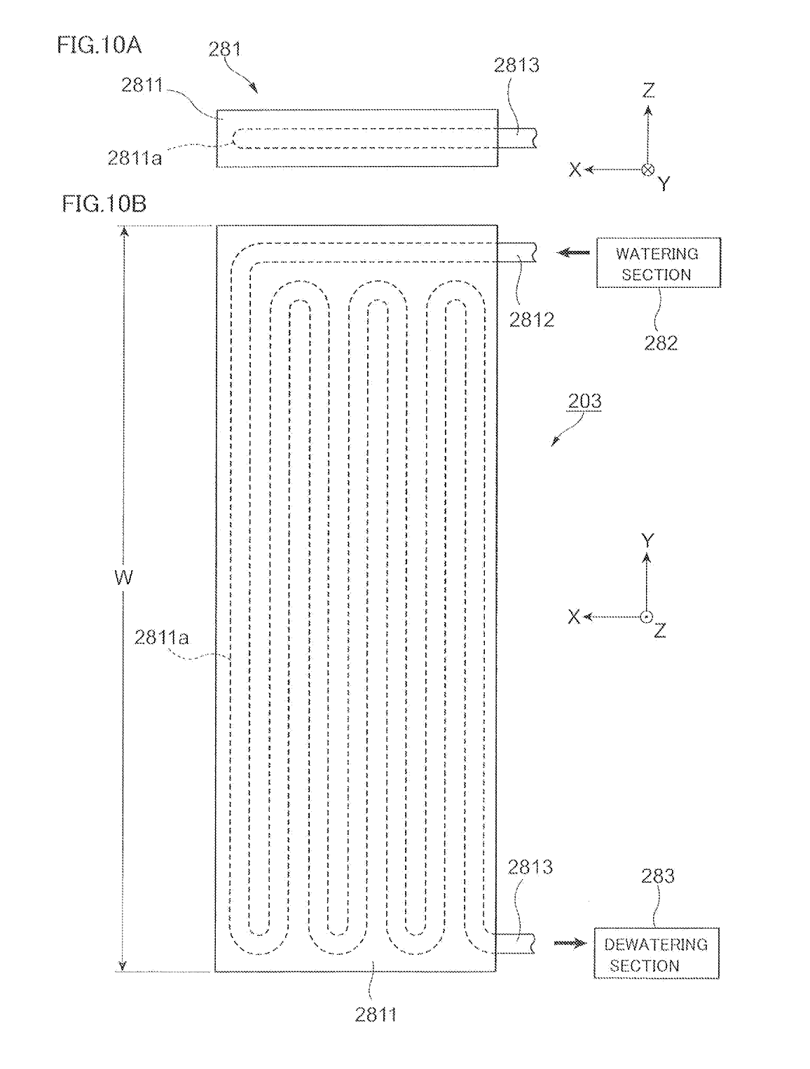

Subsequently, the cooling section 203 provided in the raw-material gas supply section 200 will be described. FIG. 10 is a diagram for illustrating a configuration of the cooling section 203 to which the exemplary embodiment is applied.

The cooling section 203 of the exemplary embodiment is, as described above, provided for cooling the raw-material gas supply duct 201. The cooling section 203 is provided on the upstream side of the raw-material gas supply duct 201 in the Z-direction (the lower side), and includes: a cooling member 281 that cools the raw-material gas; a water supply section 282 that supplies the cooling member 281 with water for cooling; and a dewatering section 283 that drains water used for cooling in the cooling member 281.

As shown in FIG. 10, the cooling member 281 of the cooling section 203 shows an outer appearance of a rectangular parallelepiped shape, and includes: a plate-like member 2811 inside of which a hollow internal piping 2811a is formed; a water supply tube 2812 that is attached to one end of the internal piping 2811a and connected to the water supply section 282, to thereby become an inlet of water of the internal piping 2811a; and a dewatering tube 2813 that is attached to the other end of the internal piping 2811a and connected to the dewatering section 283, to thereby become an outlet of water from the internal piping 2811a. It should be noted that each of the plate-like member 2811, the water supply tube 2812 and the dewatering tube 2813 that constitute the cooling member 281 is configured with stainless steel.

It should be noted that, in the cooling section 203, when the raw-material gas moving through the raw-material gas supply duct 201 is cooled, supply of the cooling water to the internal piping 2811a of the cooling member 281 is conducted by the water supply section 282 and drainage of the cooling water used by the dewatering section 283 for cooling is conducted.

### Film-Forming Operation by Use of CVD Device

Next, description will be given of a film-forming operation by use of the CVD device 1 of the exemplary embodiment.

First, the substrate S, whose film-formation surface faces outward, is loaded on the recessed portion 113a of the loading body 113. Next, on the rotating table 112 (the receiving portion 112a) of the floor section 110 in the CVD device 1, the loading body 113 on which the substrate S is loaded is set.

Subsequently, by use of the used gas discharge section 600, degassing of the interior space 100a, the first supply space 211 to the fourth supply space 241 in the raw-material gas supply section 200 and the discharge space 400a is performed, and the carrier gas is supplied to the interior space 100a by use of the raw-material gas supply section 200, as well as the blocking gas is supplied to the interior space 100a by use of the blocking gas supply section 300. This replaces the atmosphere in the interior space 100a, the first supply space 211 to the fourth supply space 241 and the discharge space 400a with the hydrogen gas (the blocking gas and the carrier gas), and reduces the pressure from a normal pressure to a predetermined pressure (in this example, 200 hPa).

At this time, a supply amount of the first blocking gas, the second blocking gas, the third blocking gas and the fourth blocking gas from the first blocking gas supply section 310, the second blocking gas supply section 320, the third blocking gas supply section 330 and the fourth blocking gas supply section 340, which constitute the blocking gas supply section 300, respectively, are selected from the range of, for example, 10 L (liter)/min to 30 L/min.

Moreover, at this time, in the raw-material gas supply section 200, the first raw-material gas introduction section 210 to the fourth raw-material gas introduction section 240 introduce the hydrogen gas (the carrier gas) to the first supply space 211 to the fourth supply space 241, and supply the interior space 100a with the hydrogen gas via the first supply space 211 to the fourth supply space 241. The supply amount of the carrier gas by each of the first raw-material gas introduction section 210 to the fourth raw-material gas introduction section 240 is selected from the range of, for example, 1 L/min to 100 L/min.

Further, in the raw-material gas supply section 200, on the occasion of supplying the interior space 100a with the carrier gas, cooling of the raw-material gas supply duct 201 is started by use of the cooling section 203.

Then, by use of the rotational driving section 800, the rotating table 112 of the floor section 110 is driven. With this, the loading body 113 set on the rotating table 112 and the substrate S loaded on the loading body 113 are rotated in the direction of arrow A. At this time, the rotation speed of the rotating table 112 (the substrate S) is 10 rpm to 20 rpm.

Next, electrical supply to the first heater 510 to the third heater 530, which constitute the heating mechanism 500, is started to cause each the first heater 510 to the third heater 530 to evolve heat, and thereby the substrate S is heated via the rotating table 112 and the loading body 113. Here, electrical supply to the first heater 510 to the third heater 530 is configured to be individually controlled, and heating control is conducted so that the temperature of the substrate S reaches a film-formation temperature selected from the range of 1500° C. to 1800° C. (in this example, 1600° C.). Moreover, with starting of heating operation by the heating mechanism 500, supply of the argon gas as the purge gas is started. Then, after the substrate S is heated to the film-formation temperature, the heating mechanism 500 changes the heating control to keep the substrate S at the film-formation temperature.

After the substrate S is heated to the film-formation temperature by the heating mechanism 500, while continuously performing supply of the blocking gas to the interior space 100a by the blocking gas supply section 300 under the above-described conditions, supply of the silicon-containing gas and the carbon-containing gas to the interior space 100a from the raw-material gas supply section 200 is started.

At this time, in the raw-material gas supply section 200, introduction of the hydrogen gas (the carrier gas) to the first supply space 211 to the fourth supply space 241 by the first raw-material gas introduction section 210 to the fourth raw-material gas introduction section 240 is continuously performed, and introduction of the silicon-containing gas (in this example, the monosilane gas) to the second supply space 221 by the second raw-material gas introduction section 220 and introduction of the carbon-containing gas (in this example, the propane gas) to the third supply space 231 by the third raw-material gas introduction section 230 are started.

Accordingly, the second raw-material gas introduced to the second supply space 221 by the second raw-material gas introduction section 220 becomes a mixed gas of the silicon-containing gas and the hydrogen gas. In addition, the third raw-material gas introduced to the third supply space 231 by the third raw-material gas introduction section 230 becomes a mixed gas of the carbon-containing gas and the hydrogen gas.

Moreover, at this time, it is preferable to start introduction of the silicon-containing gas by the second raw-material gas introduction section 220 and introduction of the carbon-containing gas by the third raw-material gas introduction section 230 simultaneously. Here, “simultaneous supply” does not require perfectly the same time, but is meant to be within a range of a few seconds.

Moreover, in the cooling section 203 of the raw-material gas supply section 200, the cooling operation is continuously conducted to cool the raw-material gas supply duct 201. This maintains the temperature of the raw-material gas supply duct 201 not more than 200° C.

It should be noted that the introduced amount of the hydrogen gas as each of the first raw-material gas introduced by the first raw-material gas introduction section 210 and the fourth raw-material gas introduced by the fourth raw-material gas introduction section 240 is selected from the range of, for example, 1 L/min to 10 L/min.

Moreover, of the second raw-material gas introduced by the second raw-material gas introduction section 220, the introduced amount of the monosilane gas is selected from the range of, for example, 50 sccm to 300 sccm, whereas, the introduced amount of the hydrogen gas is selected from the range of, for example, 1 L/min to 30 L/min. Further, of the third raw-material gas introduced by the third raw-material gas introduction section 230, the introduced amount of the propane gas is selected from the range of, for example, 12 sccm to 200 sccm, whereas, the introduced amount of the hydrogen gas is selected from the range of, for example, 1 L/min to 30 L/min. However, the introduced amounts of the monosilane gas and the propane gas are determined so that the concentration ratio of carbon and silicon, namely, C/Si ratio falls within the range of 0.8 to 2.0.

Then, the first raw-material gas to the fourth raw-material gas having been introduced by the first raw-material gas introduction section 210 to the fourth raw-material gas introduction section 240 are brought into the state of being spread in the Y-direction (the −Y-direction) in the first supply space 211 to the fourth supply space 241 of the raw-material gas supply duct 201, respectively, and thereafter, brought into the interior space 100a along the X-direction.

It should be noted that supply of the raw-material gas or the like to the interior space 100a by the raw-material gas supply section 200 will be described in detail at a later stage.

Moreover, in this example, the monosilane gas and the propane gas are used as the silicon-containing gas contained in the second raw-material gas and the carbon-containing gas contained in the third raw-material gas, respectively; however, there is no limitation to these gases. As the silicon-containing gas, for example, disilane (Si₂H₆) gas may be used. Moreover, as the carbon-containing gas, ethylene (C₂H₄) gas, ethane (C₂H₆) gas or the like may be used. Further, as the silicon-containing gas, dichlorosilane gas, trichlorosilane gas or the like containing Cl may be used. Still further, in this example, the hydrogen (H₂) gas is singly used as the carrier gas; however, it may be acceptable to use the hydrogen (H₂) gas containing hydrochloric acid (HCl) gas.

The raw-material gas brought into the interior space 100a by the raw-material gas supply section 200 reaches the periphery of the substrate S rotating in the direction of arrow A in a state of being guided in the X-direction and prevented from floating in the Z-direction (upward) by the blocking gas. Of the raw-material gas having reached the periphery of the substrate S, the monosilane gas is decomposed into silicon and hydrogen by heat transmitted via the substrate S or the like, and the propane gas is decomposed into carbon and hydrogen by heat transmitted via the substrate S or the like. Then, silicon and carbon obtained by thermal decomposition are deposited in order on the surface of the substrate S while keeping regularity, and accordingly, on the substrate S, a 4H—SiC film is epitaxially grown.

Then, the raw-material gas (including the one having already been reacted) and the blocking gas moving in the X-direction in the interior space 100a are further moved in the X-direction by the degassing operation of the used gas discharge section 600, brought into the discharge space 400a provided to the discharge duct 400 from the interior space 100a, and further, discharged to the outside of the reaction container 10.

Then, when formation of the 4H—SiC epitaxial film having a thickness required by an SiC epitaxial wafer is completed on the substrate S, the raw-material gas supply section 200 stops supplying the interior space 100a with the raw-material gas. Moreover, the heating mechanism 500 stops heating the substrate S, on which the 4H—SiC epitaxial film is laminated, and the rotational driving section 800 stops driving the rotating table 112 (rotation of the substrate S). Further, in the state where the substrate S is sufficiently cooled, supply of the blocking gas and supply of the purge gas by use of the blocking gas supply section 300 are stopped, to thereby complete a series of film-forming operations. Then, after the degassing operation by the used gas discharge section 600 is stopped and thereby the interior space 100a is returned to the normal pressure, the substrate S on which the 4H—SiC epitaxial film is laminated, namely, the SiC epitaxial wafer is taken out of the reaction container 10 together with the loading body 113, and the SiC epitaxial wafer is detached from the loading body 113.

### Supply of Raw-Material Gas by Raw-Material Gas Supply Section

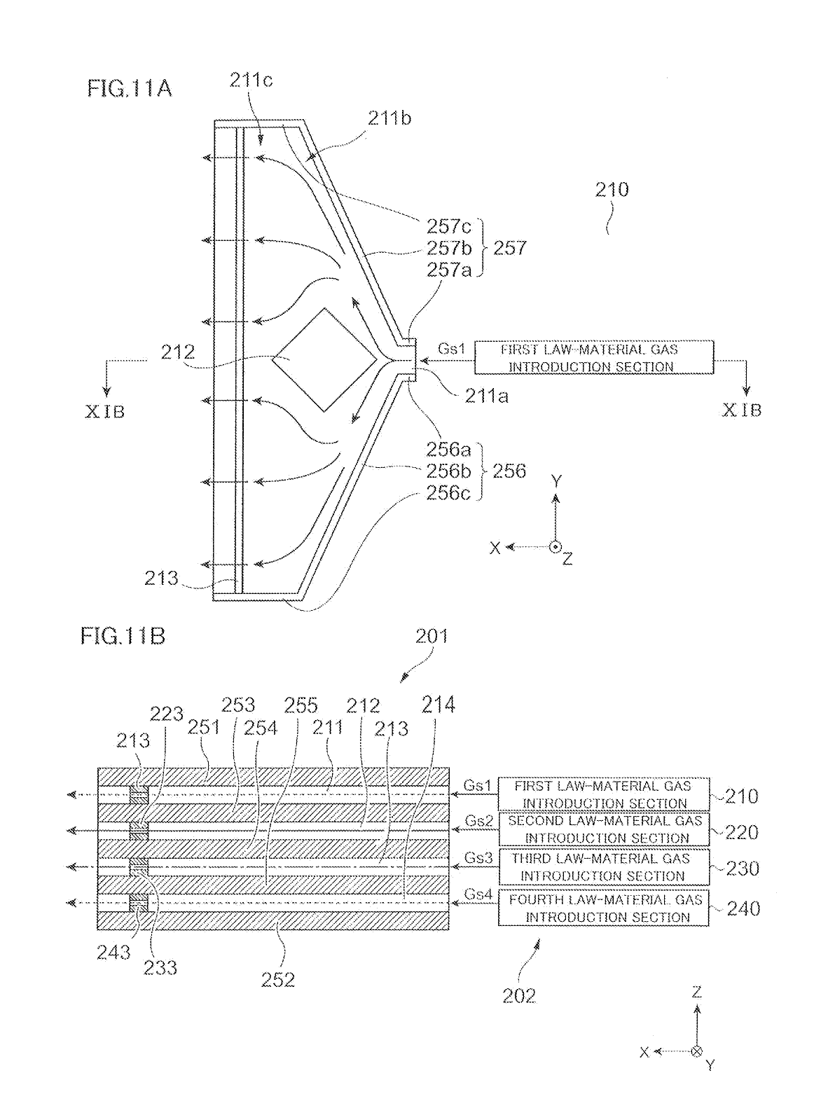

FIGS. 11A and 11B are diagrams schematically showing a flow of the raw-material gas when the raw-material gas is supplied from the raw-material gas supply section 200 to which the exemplary embodiment is applied. FIG. 11A is a diagram showing a flow of the first raw-material gas Gs1 in the first supply space 211 of the raw-material gas supply section 200, and FIG. 11B is an XIB-XIB cross-sectional view in FIG. 11A. It should be noted that, in FIG. 11B, illustration of the first diffusion plate 212, the second diffusion plate 222, the third diffusion plate 232 and the fourth diffusion plate 242 is omitted.

As shown in FIG. 11A, with starting the above-described film-forming operations, the first raw-material gas introduction section 210 introduces the first raw-material gas Gs1 to the first introduction region 211a in the first supply space 211. The first raw-material gas Gs1 introduced to the first introduction region 211a is moved along the X-direction by a propulsive force imparted by the first raw-material gas introduction section 210 and an absorptive force generated by the degassing operation of the used gas discharge section 600 (refer to FIG. 1), and reaches the first diffusion region 211b.

The first raw-material gas Gs1 having reached the first diffusion region 211b further moves along the X-direction. As described above, the first diffusion region 211b is configured so that the first duct angle θ1 formed by the first middle section 256b of the first duct side wall 256 and the second middle section 257b of the second duct side wall 257 becomes an obtuse angle, and the first diffusion region 211b is formed so that the width along the Y-direction thereof gradually extends from the upstream end in the X-direction connected to the first introduction region 211a toward the downstream end in the X-direction connected to the first discharge region 211c.

Accordingly, the first raw-material gas Gs1 having reached the first diffusion region 211b from the first introduction region 211a is guided by the first middle section 256b and the second middle section 257b, and is thereby moved in the X-direction while diffusing in the Y-direction and −Y-direction with expanding of the width of the first diffusion region 211b.

Further, in the exemplary embodiment, the first diffusion plate 212 is formed to extend over the first diffusion region 211b and the first discharge region 211c. This causes the first raw-material gas Gs1 moving in the X-direction in the first diffusion region 211b to reach the first diffusion plate 212 in due time. Then, the first raw-material gas Gs1 having reached the first diffusion plate 212 changes the moving direction thereof by bumping against the first diffusion plate 212, and after extending in the Y-direction (the −Y-direction) so as to avoid the first diffusion plate 212, further moves in the X-direction.

Then, the first raw-material gas Gs1 reaches the first discharge region 211c in the state of being diffused in the Y-direction (the −Y-direction).

The first raw-material gas Gs1 having reached the first discharge region 211c further moves along the X-direction.

As described above, in the first discharge region 211c, the first flow-adjusting member 213 is provided, and accordingly, the first raw-material gas Gs1 having reached the first discharge region 211c and moving in the X-direction is to reach the first flow-adjusting member 213 in due time. Then, the first raw-material gas Gs1 reached the first flow-adjusting member 213 passes through the plural first through holes 213a provided in the first flow-adjusting member 213, to further move toward the downstream side in the X-direction.

Here, since the first raw-material gas Gs1 is diffused in the Y-direction (the −Y-direction) in the first diffusion region 211b as described above, the moving direction of the first raw-material gas Gs1 having reached the first discharge region 211c from the first diffusion region 211b is obliquely inclined toward the Y-direction (the −Y-direction) with respect to the X-direction in some cases. Then, in the first discharge region 211c, the flow of the first raw-material gas Gs1 like this is to be adjusted so that the moving direction thereof is along the X-direction by passing through the first through holes 213a provided along the X-direction in the first flow-adjusting member 213.

Then, the first raw-material gas having passed through the first flow-adjusting member 213 in the first discharge region 211c moves along the X-direction in the state of being diffused in the Y-direction (the −Y-direction), to be thereby discharged toward the interior space 100a of the container chamber 100 (refer to FIG. 1).

In this manner, in the raw-material gas supply section 200 of the exemplary embodiment, since the raw-material gas supply duct 201 has the configuration as described above, as compared to a case where the present configuration is not employed, it becomes possible to cause the raw-material gas supply duct 201 to uniformly discharge the raw-material gas, and it becomes possible to cause the flow rate of the raw-material gas discharged from the raw-material gas supply duct 201 to be substantially uniform from the upstream side in the Y-direction to the downstream side in the Y-direction.

In other words, for example, in a case where the first duct angle θ1 is an acute angle, since the first raw-material gas introduced from the first raw-material gas introduction section 210 to the first supply space 211 is hardly diffused in the Y-direction (the −Y-direction), the first raw-material gas is prone to concentrate at the center portion in the Y-direction of the raw-material gas supply duct 201. As a result, the first raw-material gas supplied from the first supply space 211 to the interior space 100a tends to be high in the flow rate at the center portion in the Y-direction and to be low in the flow rate at both end portions in the Y-direction, and accordingly, the flow rate is prone to be non-uniform along the Y-direction.

In contrast thereto, in the exemplary embodiment, the first duct angle θ1 is configured to be an obtuse angle, and thereby, in the first diffusion region 211b, the first raw-material gas tends to be diffused along the Y-direction (the −Y-direction). In particular, the first supply space 211 of the exemplary embodiment is provided with the first diffusion plate 212, and accordingly, the first raw-material gas is diffused toward the upstream side and the downstream side in the Y-direction in the first supply space 211 so as to avoid the first diffusion plate 212. Consequently, with respect to the first raw-material gas discharged by the first supply space 211, as compared to the case where the present configuration is not employed, it becomes possible to increase the flow rate in the upstream side and the downstream side in the Y-direction, and to decrease the flow rate at the center portion in the Y-direction positioned at the downstream side in the X-direction of the first diffusion plate 212. As a result, it becomes possible to cause the flow rate of the raw-material gas discharged from the first supply space 211 of the raw-material gas supply duct 201 to be substantially uniform over a range from the upstream side in the Y-direction to the downstream side in the Y-direction.

It should be noted that, in the above description, the flow of the first raw-material gas Gs1 in the first supply space 211, of the first supply space 211 to the fourth supply space 241, was taken as an example; however, flows of the second raw-material gas Gs2 to the fourth raw-material gas Gs4 in the second supply space 221 to the fourth supply space 241, respectively, are similar to the flow of the first raw-material gas Gs1.

In other words, the second raw-material gas Gs2 to the fourth raw-material gas Gs4 are introduced from the second raw-material gas introduction section 220 to the fourth raw-material gas introduction section 240 to the introduction regions (not shown) of the second supply space 221 to the fourth supply space 241, respectively. Thereafter, after the second raw-material gas Gs2 to the fourth raw-material gas Gs4 move along the X-direction to reach the diffusion regions (not shown), to be diffused in the Y-direction (the −Y-direction) via the second diffusion plate 222 to the fourth diffusion plate 242 (each refer to FIG. 7), respectively, the second raw-material gas Gs2 to the fourth raw-material gas Gs4 pass through the second flow-adjusting member 223 to the fourth flow-adjusting member 243, and are discharged from the discharge region (not shown) toward the interior space 100a.

Here, in the raw-material gas supply duct 201 of the exemplary embodiment, the first supply space 211, the second supply space 221, the third supply space 231 and the fourth supply space 241 are configured to be laminated in this order along the −Z-direction.

Accordingly, with respect to the raw-material gas, as shown in FIG. 11B, the first raw-material gas Gs1 from the first supply space 211, the second raw-material gas Gs2 from the second supply space 221, the third raw-material gas Gs3 from the third supply space 231 and the fourth raw-material gas Gs4 from the fourth supply space 241 are discharged from the raw-material gas supply duct 201 along the −Z-direction in the state of being layered in this order, to be supplied to the interior space 100a (refer to FIG. 1).

To put another way, in the exemplary embodiment, the second raw-material gas Gs2 containing the silicon-containing gas (the monosilane gas) and the third raw-material gas Gs3 containing the carbon-containing gas (the propane gas) and placed below the second raw-material gas Gs2 (on the upstream side in the Z-direction) are supplied to the interior space 100a in the state of being sandwiched between the first raw-material gas Gs1 and the fourth raw-material gas Gs4, which are the carrier gas (the hydrogen gas).

Moreover, as described above, when the raw-material gas Gs is supplied by the raw-material gas supply section 200 to the interior space 100a, the raw-material gas supply duct 201 is cooled by the cooling section 203 (refer to FIG. 7).

Accordingly, for example, it is possible to suppress thermal decomposition of the silicon-containing gas (the monosilane gas) contained in the second raw-material gas Gs2 or the carbon-containing gas (the propane gas) contained in the third raw-material gas Gs3 in the raw-material gas supply duct 201, or to suppress blockage in the second supply space 221 or the third supply space 231 caused by the Si or C generated by the thermal decomposition.

It should be noted that each wall (the duct upper wall 251, the duct lower wall 252, the first duct dividing wall 253, the second duct dividing wall 254, the third duct dividing wall 255, the first duct side wall 256 and the second duct side wall 257) constituting the raw-material gas supply duct 201 of the exemplary embodiment is configured with stainless steel. Moreover, the first diffusion plate 212 to the fourth diffusion plate 242 and the first flow-adjusting member 213 to the fourth flow-adjusting member 243 are configured with stainless steel.

In general, when a component member made of stainless steel is brought into contact with the carbon-containing gas under the temperature condition of not less than 300° C., a phenomenon called carburization, in which properties of the surface of stainless steel are changed by the carbon-containing gas, is caused in some cases. Then, in the case where properties of the surface of stainless steel are changed by carburization, there is a worry that the component member made of stainless steel becomes brittle and strength thereof is decreased.

In the exemplary embodiment, inside of the raw-material gas supply duct 201 is prevented from becoming high temperature by cooling the raw-material gas supply duct 201 by the cooling section 203. This makes it possible to suppress occurrence of carburization in each wall constituting the raw-material gas supply duct 201.

In particular, in the raw-material gas supply duct 201 of the exemplary embodiment, the third supply space 231 for supplying the third raw-material gas Gs3 containing the carbon-containing gas (the propane gas) is, as compared to the second supply space 221 for supplying the second raw-material gas Gs2 containing the silicon-containing gas (the monosilane gas), arranged on the lower side (the upstream side in the Z-direction) that is closer to the cooling member 281 in the cooling section 203. Accordingly, as compared to the case where the present configuration is not employed, it is possible to suppress rise of the temperature of the third raw-material gas Gs3 containing the carbon-containing gas, and it becomes possible to better suppress occurrence of carburization within the raw-material gas supply duct 201.

Moreover, in the raw-material gas supply duct 201 of the exemplary embodiment, by the first supply space 211, the second supply space 221, the third supply space 231 and the fourth supply space 241, which are divided from one another by the first duct dividing wall 253, the second duct dividing wall 254 and the third duct dividing wall 255, the first raw-material gas Gs1 to the fourth raw-material gas Gs4 are separately supplied.

Accordingly, in the exemplary embodiment, when the raw-material gas Gs is supplied to the interior space 100a via the raw-material gas supply duct 201, the first raw-material gas Gs1 to the fourth raw-material gas Gs4, which move in the first supply space 211 to the fourth supply space 241, respectively, do not contact one another. In other words, in the exemplary embodiment, the second raw-material gas Gs2 containing the silicon-containing gas (the monosilane gas) and the third raw-material gas Gs3 containing the carbon-containing gas (the propane gas) do not contact directly in the raw-material gas supply duct 201. Consequently, in the raw-material gas supply duct 201, it is possible to suppress reaction of the silicon-containing gas and the carbon-containing gas, and accordingly, it is possible to suppress adhesion of reaction products of the silicon-containing gas and the carbon-containing gas to the inside of the raw-material gas supply duct 201.

### Flow of Raw-Material Gas and Blocking Gas Supplied to Container Chamber

Subsequently, flow of the raw-material gas and the blocking gas supplied to the container chamber 100 will be described.

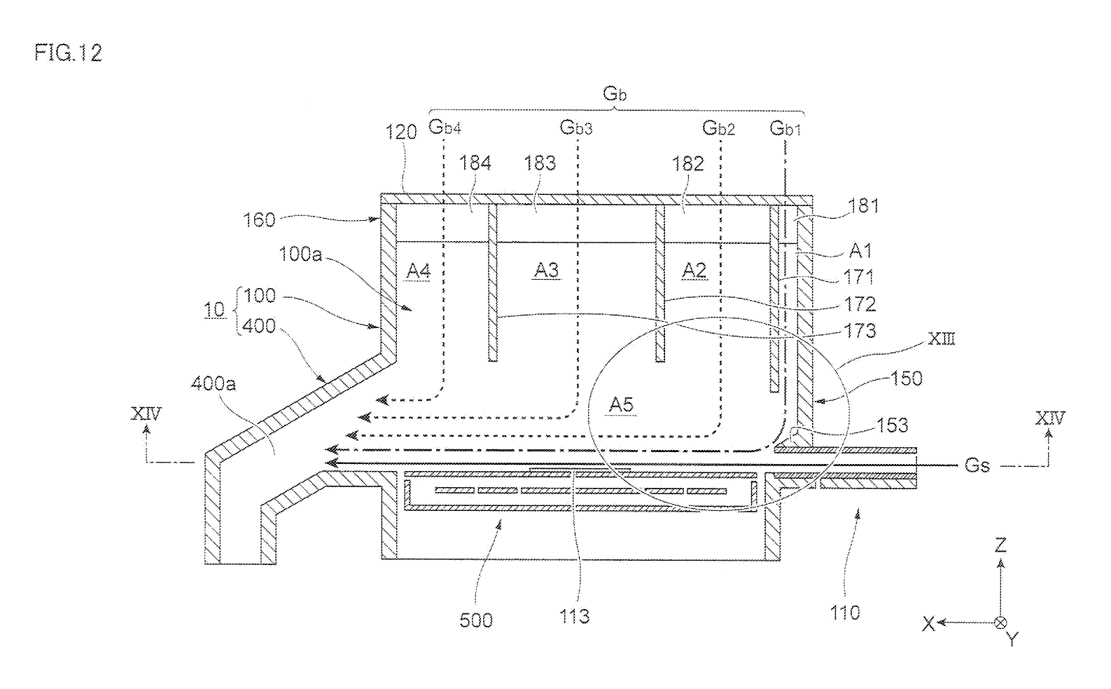

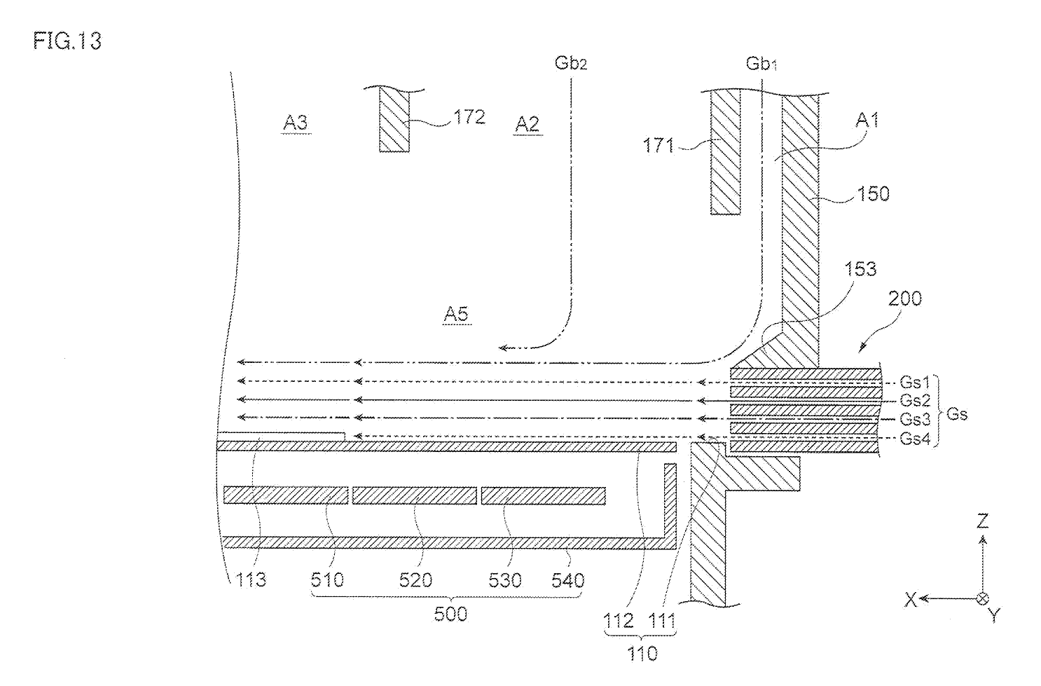

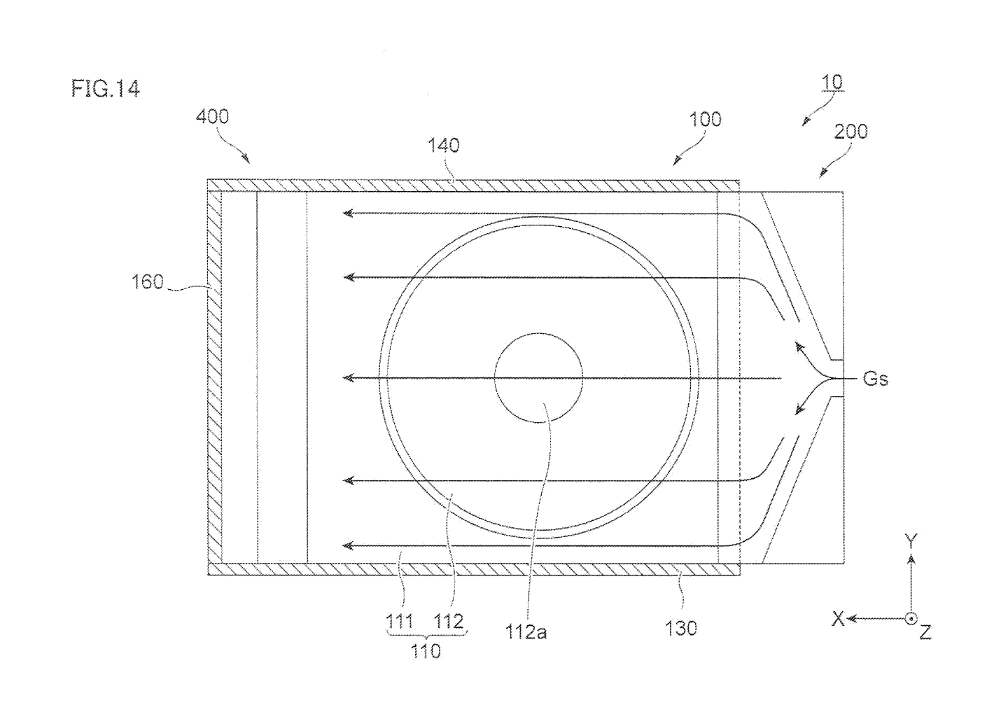

FIG. 12 is a diagram schematically showing the flow of the raw-material gas and the blocking gas in the container chamber 100. Moreover, FIG. 13 is an enlarged view of a XIII part in FIG. 12. Further, FIG. 14 is a XIV-XIV cross-sectional view in FIG. 12.

First, the raw-material gas Gs (the first raw-material gas Gs1 to the fourth raw-material gas Gs4) having been supplied from the raw-material gas supply section 200 to the interior space 100a is carried into the fifth region A5 from a portion below the first region A1. Here, the raw-material gas Gs to be supplied to the interior space 100a is, as described above, in the state where the first raw-material gas Gs1, the second raw-material gas Gs2, the third raw-material gas Gs3 and the fourth raw-material gas Gs4 are layered along the −Z-direction in this order. In other words, the second raw-material gas Gs2 containing the silicon-containing gas (the monosilane gas) and the third raw-material gas Gs3 containing the carbon-containing gas (the propane gas) are supplied to the interior space 100a while being sandwiched between the first raw-material gas Gs1 and the fourth raw-material gas G4.

Consequently, the second raw-material gas Gs2 and the third raw-material gas Gs3 are moved along the X-direction in a state where movement thereof along the Z-direction (the −Z-direction) is suppressed by the first raw-material gas Gs1 and the fourth raw-material gas Gs4. To put another way, the first raw-material gas Gs1 and the fourth raw-material gas Gs4 have a role in assisting the second raw-material gas Gs2 and the third raw-material gas Gs3 in moving in the X-direction.

Then, the raw-material gas Gs carried into the fifth region A5 is moved along the X-direction toward the loading body 113 (the substrate S) by a propulsive force imparted by the raw-material gas supply section 200 and an absorptive force generated by the degassing operation of the used gas discharge section 600 (refer to FIG. 1) in the state where the first raw-material gas Gs1 to the fourth raw-material gas Gs4 are layered, while facing the floor section 110.

Moreover, as described above, the discharge width Wd in the raw-material gas supply duct 201 of the exemplary embodiment is equal to the interior width W in the container chamber 100. Then, the raw-material gas Gs (the first raw-material gas Gs1 to the fourth raw-material gas Gs4) is extended in the raw-material gas supply duct 201 along the Y-direction (the −Y-direction) up to the interior width W, and thereafter, supplied to the interior space 100a in the state where the moving direction thereof is adjusted to head in the X-direction. In other words, the raw-material gas Gs is, when being supplied to the interior space 100a from the raw-material gas supply duct 201, moved along the X-direction, continuously, without changing the moving direction thereof.

Moreover, as described above, in the exemplary embodiment, the raw-material gas Gs supplied from the raw-material gas supply duct 201 to the interior space 100a has a flow rate that is substantially uniform from the upstream side to the downstream side in the Y-direction.

This makes it possible, in the exemplary embodiment, to suppress occurrence of a vortex or fluctuations in the flow of the raw-material gas Gs in the interior space 100a.

Moreover, the first blocking gas Gb1 supplied from the first blocking gas supply section 310 (refer to FIG. 1) to the first region A1 is diffused within the range of the first region A1 in the X-direction and the Y-direction by the first blocking gas diffusion member 181, while lowering along the -Z-direction. The first blocking gas Gb1 having passed through the first blocking gas diffusion member 181 is further lowered along the −Z-direction within the first region A1, and is carried from the first region A1 into the fifth region A5. Here, below the first region A1, the protruding member 153 provided in the third side wall 150 is positioned. For this reason, the first blocking gas Gb1 carried into the fifth region A5 changes the moving direction thereof from the direction along the −Z-direction to the direction along the X-direction by being guided by the inclined surface provided to the protruding member 153 and pulled by the absorptive force of the used gas discharge section 600 (refer to FIG. 1). While changing the moving direction from the -Z-direction to the X-direction, the first blocking gas Gb1 bumps against the raw-material gas Gs moving in the fifth region A5 along the X-direction. Then, the first blocking gas Gb1, whose moving direction has been changed into the X-direction, moves along the X-direction toward a portion of the fifth region A5 positioned below the second region A2, together with the raw-material gas Gs. At this time, the first blocking gas Gb1 moving toward the X-direction is brought into a state of covering an upper portion of the raw-material gas Gs (the first raw-material gas Gs1) similarly moving toward the X-direction, to thereby suppress floating upward (the first region A1 side) of the raw-material gas Gs moving toward the X-direction. As a result, it is possible to prevent the raw-material gas Gs from entering the first region A1, and by extension, from reaching a portion, of the ceiling 120, which is an upper end of the first region A1.

Here, through the supply space 200a, the raw-material gas Gs having moved to the portion, of the fifth region A5 in the interior space 100a, below the first region A1 is to expand in a stroke because the pressure in the interior space 100a is lower than the pressure in the supply space 200a. Moreover, the raw-material gas Gs, which has moved from the portion, of the fifth region A5, below the first region A1 to the portion below the second region A2, expands by receiving heat by the heating mechanism 500 via the rotating table 112 and nearly floats from the lower side to the upper side. At this time, the first blocking gas Gb1 moving along the X-direction together with the raw-material gas Gs suppresses floating upward of the raw-material gas Gs.

Here, in the exemplary embodiment, the second raw-material gas Gs2 containing the monosilane gas, which is the silicon-containing gas, and the third raw-material gas Gs3 containing the propane gas, which is the carbon-containing gas, are supplied to the interior space 100a in the state of being sandwiched between the first raw-material gas Gs1 and the fourth raw-material gas Gs4. Then, the second raw-material gas Gs2 and the third raw-material gas Gs3 move in the interior space 100a along the X-direction in a state where the upper portion thereof (the first region A1 side) is covered with the first raw-material gas G1.

In this case, when bumping against the raw-material gas Gs, the first blocking gas Gb1 is to bump against the first raw-material gas Gs1, of the raw-material gas Gs, and is less likely to directly bump against the second raw-material gas Gs2 and the third raw-material gas Gs3. This makes it possible to suppress occurrence of fluctuations in the flow of the second raw-material gas Gs2 and the third raw-material gas Gs3, occurrence of floating upward of the second raw-material gas Gs2 and the third raw-material gas Gs3, and the like, caused by being bumped by the first blocking gas Gb1.

Moreover, the second blocking gas Gb2 supplied from the second blocking gas supply section 320 (refer to FIG. 1) to the second region A2 is diffused within the range of the second region A2 in the X-direction and the Y-direction by the second blocking gas diffusion member 182, while lowering along the −Z-direction. The second blocking gas Gb2 having passed through the second blocking gas diffusion member 182 is further lowered along the −Z-direction within the second region A2, and is carried from the second region A2 into the fifth region A5. Accordingly, the second blocking gas Gb2 carried from the second region A2 into the fifth region A5 along the −Z-direction results in pressing the raw-material gas Gs and the first blocking gas Gb1, which exist in a portion, of the fifth region 5A, below the second region A2, from above. Consequently, together with the first blocking gas Gb1, the second blocking gas Gb2 carried into the fifth region A5 along the −Z-direction suppresses floating upward of the raw-material gas Gs moving along the X-direction. As a result, it is possible to prevent the raw-material gas Gs from entering the second region A2, and by extension, from reaching a portion, of the ceiling 120, which is an upper end of the second region A2.

It should be noted that the second blocking gas Gb2 having moved along the −Z-direction changes the moving direction thereof from the direction along the −Z-direction to the direction along the X-direction by being pulled by the absorptive force of the used gas discharge section 600 (refer to FIG. 1). Then, the second blocking gas Gb2, whose moving direction has been changed into the X-direction, moves along the X-direction toward a portion, of the fifth region A5, positioned below the third region A3, together with the raw-material gas Gs and the first blocking gas Gb1.

The raw-material gas Gs, which has moved from the portion, of the fifth region A5, below the second region A2 to the portion below the third region A3, expands by receiving heat by the heating mechanism 500 via the rotating table 112, the loading body 113 and the substrate S and nearly floats from the lower side to the upper side. At this time, the first blocking gas Gb1 and the second blocking gas Gb2 moving along the X-direction together with the raw-material gas Gs suppress floating upward of the raw-material gas Gs.

Moreover, the third blocking gas Gb3 supplied from the third blocking gas supply section 330 (refer to FIG. 1) to the third region A3 is diffused within the range of the third region A3 in the X-direction and the Y-direction by the third blocking gas diffusion member 183, while lowering along the −Z-direction. The third blocking gas Gb3 having passed through the third blocking gas diffusion member 183 is further lowered along the −Z-direction within the third region A3, and is carried from the third region A3 into the fifth region A5. Accordingly, the third blocking gas Gb3 carried from the third region A3 into the fifth region A5 along the −Z-direction results in pressing the raw-material gas Gs, the first blocking gas Gb1 and the second blocking gas Gb2 which exist in a portion, of the fifth region 5A, below the third region A3, from above. Consequently, together with the first blocking gas Gb1 and the second blocking gas Gb2, the third blocking gas Gb3 carried along the −Z-direction suppresses floating upward (the third region A3) of the raw-material gas Gs moving along the X-direction. As a result, it is possible to prevent the raw-material gas Gs from entering the third region A3, and by extension, from reaching a portion, of the ceiling 120, which is an upper end of the third region A3.

It should be noted that the third blocking gas Gb3 having moved along the −Z-direction changes the moving direction thereof from the direction along the −Z-direction to the direction along the X-direction by being pulled by the absorptive force of the used gas discharge section 600 (refer to FIG. 1). Then, the third blocking gas Gb3, whose moving direction has been changed into the X-direction, moves along the X-direction toward a portion, of the fifth region A5, positioned below the fourth region A4, together with the raw-material gas Gs, the first blocking gas Gb1 and the second blocking gas Gb2.

Here, at a portion, of the fifth region A5, positioned below the third region A3, as described above, the loading body 113 and the substrate S loaded on the loading body 113 are arranged. Then, at this portion, the raw-material gas Gs is pressed against the substrate S side by use of the first blocking gas Gb1 to the third blocking gas Gb3, and accordingly, most of the raw-material gas Gs exists around the substrate S. At this time, the substrate S has been heated to the film-forming temperature by the heating mechanism 500 (refer to FIG. 3), and thereby, of the raw-material gas Gs existing around the substrate S, the monosilane gas contained in the second raw-material gas Gs2 and the propane gas contained in the third raw-material gas Gs3 are subjected to thermal decomposition with heating via the substrate S and the like, and on the substrate S, the 4H—SiC single crystal by Si and C obtained by the thermal decomposition is epitaxially grown. However, all of Si and C obtained by the thermal decomposition is not used for the epitaxial growth on the substrate S, and a part thereof moves along the X-direction together with the first blocking gas Gb1 to the third blocking gas Gb3. Moreover, the hydrogen gas (reacted gas) obtained by thermal decomposition of the monosilane gas and the propane gas also moves along the X-direction together with the first blocking gas Gb1 to the third blocking gas Gb3. Further, part of the monosilane gas and part of the propane gas are not subjected to the thermal decomposition around the substrate S, and move along the X-direction as they are.

By the way, in general, as the carbon-containing gas, such as the propane gas, and the silicon-containing gas, such as the monosilane gas are compared, the carbon-containing gas has a property that is less likely to be decomposed by heat, whereas, the silicon-containing gas has a property that is more likely to be decomposed by heat.

Here, as described above, in the exemplary embodiment, the raw-material gas Gs is supplied to the interior space 100a in the state where the first raw-material gas Gs1 to the fourth raw-material gas Gs4 are layered in the −Z-direction, and after moving through the fifth region A5, which is positioned below the first region A1, the second region A2 and the third region A3, reaches the substrate S. Then, in the fifth region A5 positioned below the second region A2 and the third region A3, the raw-material gas Gs moves in the X-direction while being heated by the first heater 510 to the third heater 530 of the heating mechanism 500 via the fixing section 111 and the rotating table 112. Moreover, the raw-material gas Gs having reached the substrate S is heated by the first heater 510 via the rotating table 112, the loading body 113 and the substrate S.

Accordingly, in the raw-material gas Gs in the exemplary embodiment, the third raw-material gas Gs3 containing the propane gas, which is the carbon-containing gas, reaches the substrate S by moving through the fifth region A5 at a position close to the heating mechanism 500 (the first heater 510 to the third heater 530) as compared to the second raw-material gas Gs2 containing the monosilane gas, which is the silicon-containing gas.

As a result, it becomes possible to heat the third raw-material gas Gs3 containing the carbon-containing gas (the propane gas) efficiently by the second heater 520 and the third heater 530 in the fifth region 5A, as compared to the case where the present configuration is not employed. Further, when the raw-material gas Gs reaches the substrate S, as compared to the case where the present configuration is not employed, it becomes possible to heat the third raw-material gas Gs3 efficiently by the first heater 510 via the substrate S, and thereby it becomes possible to accelerate thermal decomposition of the carbon-containing gas on the substrate S.

Moreover, with respect to the second raw-material gas Gs2 containing the silicon-containing gas (the monosilane gas), which is likely to be subjected to the thermal decomposition, it is possible to prevent from being overheated by the second heater 520 and the third heater 530 in the fifth region, and to suppress proceeding of the thermal decomposition due to heating by the heating mechanism 500 before reaching the substrate S, as compared to the case where the present configuration is not employed. It should be noted that, since the monosilane gas is more likely to be subjected to the thermal decomposition than the propane gas, thermal decomposition of the monosilane gas on the substrate S is hardly be insufficient even in the case where the second raw-material gas Gs2 moves at a position away from the heating mechanism 500, as compared to the third raw-material gas Gs3.

This makes it possible to prevent the concentration ratio between a growth seed generated by the thermal decomposition of the carbon-containing gas and a growth seed generated by the thermal decomposition of the silicon-containing gas from becoming non-uniform on the substrate S. Then, on the substrate S, it becomes possible to equalize the ratio between C obtained by the thermal decomposition of the carbon-containing gas and Si obtained by the thermal decomposition of the silicon-containing gas, and therefore, it becomes possible to properly control the C/Si ratio on the substrate S.

As a result, with respect to the 4H—SiC single crystal epitaxial film formed on the substrate S, it becomes possible to suppress degradation of a film quality, such as deterioration of the surface morphology caused by the difference in the epitaxial growth mode. Moreover, in the case where a different element to be a dopant of the hole-conduction type (the p-type) or the electron-conduction type (the n-type) is contained in the raw-material gas, with respect to the SiC film formed on the substrate S, it becomes possible to suppress occurrence of accidents, such as non-uniformity in the carrier concentration distribution.

Further, it is possible to prevent most of the monosilane gas contained in the second raw-material gas Gs2 from being decomposed by heat before reaching the substrate S, or to prevent most of the propane gas contained in the third raw-material gas Gs3 from passing through the substrate S without being decomposed by heat, and accordingly, it becomes possible to cause the thermal decomposition of the monosilane gas and the propane gas to tend to occur on the substrate S. As a result, as compared to the case where the present configuration is not employed, it becomes possible to efficiently conduct epitaxial growth of the SiC film on the substrate S.

Subsequently, the raw-material gas Gs (including the unreacted gas and the reacted gas) having moved to a portion below the fourth region A4 from the portion below the third region A3, of the fifth region A5, expands upon receiving heat from the heating mechanism 500 via the rotating table 112, and nearly floats from the lower side toward the upper side. At this time, the first blocking gas Gb1 to the third blocking gas Gb3 moving along the X-direction, together with the raw-material gas Gs, suppress floating upward of the raw-material gas Gs.

Moreover, the fourth blocking gas Gb4 supplied from the fourth blocking gas supply section 340 (refer to FIG. 1) to the fourth region A4 is diffused in the X-direction and the Y-direction within the range of the fourth region A4 by the fourth blocking gas diffusion member 184 while lowering along the −Z-direction. The fourth blocking gas Gb4 having passed through the fourth blocking gas diffusion member 184 is further lowered along the −Z-direction within the fourth region A4, and is carried from the fourth region A4 into the fifth region A5. Accordingly, the fourth blocking gas Gb4 carried from the fourth region A4 into the fifth region A5 along the −Z-direction results in pressing the raw-material gas Gs and the first blocking gas Gb1 to the third blocking gas Gb3 which exist in a portion, of the fifth region 5A, below the fourth region A4, from above. Consequently, together with the first blocking gas Gb1 to the third blocking gas Gb3, the fourth blocking gas Gb4 carried along the −Z-direction suppresses floating upward (the fourth region A4) of the raw-material gas Gs moving along the X-direction. As a result, it is possible to prevent the raw-material gas Gs from entering the fourth region A4, and by extension, from reaching a portion, of the ceiling 120, which is an upper end of the fourth region A4.

It should be noted that the fourth blocking gas Gb4 having moved along the −Z-direction changes the moving direction thereof from the direction along the −Z-direction to the direction along the X-direction by being pulled by the absorptive force of the used gas discharge section 600 (refer to FIG. 1). Then, the fourth blocking gas Gb4, whose moving direction has been changed into the X-direction, moves along the X-direction toward a communication portion between the fifth region A5 and the discharge space 400a, together with the raw-material gas Gs and the first blocking gas Gb1 to the third blocking gas Gb3. Then, the raw-material gas Gs and the first blocking gas Gb1 to the fourth blocking gas Gb4 are discharged to the outside by the used gas discharge section 600 via the discharge space 400a.

It should be noted that, since the ceiling 120 is apart from the heating mechanism 500 and the blocking gas is supplied to the fifth region A5 via the first region A1 to the fourth region A4, the ceiling 120 is maintained at the temperature of not more than 50° C., even though the ceiling 120 is not directly cooled.

In this manner, in the exemplary embodiment, the first blocking gas Gb1 and the second blocking gas Gb2 play a role in guiding the raw-material gas Gs along the X-direction toward the substrate S side, the third blocking gas Gb3 plays a role in pressing the raw-material gas Gs passing through the substrate S along the X-direction against the substrate S from above, and the fourth blocking gas Gb4 plays a role in guiding the raw-material gas having passed through the substrate S toward the discharge duct 400 side along the X-direction.

Here, it is assumed that the moving speed of the first blocking gas Gb1 carried from the first region A1 to the fifth region A5 is a first blocking gas flow rate Vb1, the moving speed of the second blocking gas Gb2 carried from the second region A2 to the fifth region A5 is a second blocking gas flow rate Vb2, the moving speed of the third blocking gas Gb3 carried from the third region A3 to the fifth region A5 is a third blocking gas flow rate Vb3, and the moving speed of the fourth blocking gas Gb4 carried from the fourth region A4 to the fifth region A5 is a fourth blocking gas flow rate Vb4. If it is assumed that the supply amount of each of the first blocking gas Gb1 to the fourth blocking gas Gb4 is, for example, 10 L (liter)/min, each flow rate is determined by the area of each of the first region A1 to the fourth region A4 on the XY plane. In the exemplary embodiment, as described above, since the lengths of the first region A1 to the fourth region A4 in the Y-direction is the interior width W and is constant, variety in the area is determined by the lengths of these first region A1 to fourth region A4 in the X-direction. Then, in the exemplary embodiment, as described above, the first region length L1, the second region length L2, the third region length L3 and the fourth region length L4, which are the lengths of the first region A1 to the fourth region A4 in the X-direction, respectively, have the relation specified by the expression L1<L4<L2<L3. Accordingly, the areas on the XY plane have the relation specified by the expression A1<A4<A2<A3, and the flow rates result in having the relation specified by the expression Vb3<Vb2<Vb4<Vb1.

As described above, the raw-material gas supply section 200 of the exemplary embodiment was configured to supply the interior space 100a of the container chamber 100 containing the substrate S with the first raw-material gas, which is the carrier gas (the hydrogen gas), the second raw-material gas, which is the mixed gas of the carrier gas (the hydrogen gas) and the silicon-containing gas (the monosilane gas), the third raw-material gas, which is the mixed gas of the carrier gas (the hydrogen gas) and the carbon-containing gas (the propane gas) and the fourth raw-material gas, which is the carrier gas (the hydrogen gas) in the layered state stacked in this order along the −Z-direction. Then, the third raw-material gas containing the carbon-containing gas, which is less likely to be decomposed by heat, was set to move within the interior space 100a in a state closer to the heating mechanism 500 provided at the lower side (the upstream side in the Z-direction) of the interior space 100a than the second raw-material gas containing the silicon-containing gas, which is likely to be decomposed by heat, as compared to the carbon-containing gas.

As a result, it is possible, in the interior space 100a, to accelerate the thermal decomposition of the carbon-containing gas, which is less likely to be decomposed by heat, and to suppress the excessive thermal decomposition of the silicon-containing gas, which is more likely to be decomposed by heat.

This makes it possible, on the substrate S arranged in the interior space 100a, to efficiently conduct epitaxial growth of the 4H—SiC single crystal configured with C obtained by the thermal decomposition of the carbon-containing gas and Si obtained by the thermal decomposition of the silicon-containing gas.

Further, in the raw-material gas supply duct 201 in the raw-material gas supply section 200 of the exemplary embodiment, the first duct side wall 256 has the first upstream section 256a, the first middle section 256b and the first downstream section 256c, and the second duct side wall 257 has the second upstream section 257a, the second middle section 257b and the second downstream section 257c. Then, in the case of being viewed from the Z-direction, the first duct angle θ1 formed by the first middle section 256b and the second middle section 257b is an obtuse angle. Further, both of the second duct angle θ2 formed by the first middle section 256b and the first downstream section 256c and the third duct angle θ3 formed by the second middle section 257b and the second downstream section 257c are obtuse angles. Accordingly, in each of the first supply space 211 to the fourth supply space 241 of the raw-material gas supply duct 201, the introduction region (the first introduction region 211a) into which the raw-material gas is introduced from the raw-material gas introduction section 202, the diffusion region (the first diffusion region 211b) for diffusing the raw-material gas in the Y-direction (the −Y-direction) and the discharge region (the first discharge region 211c) for adjusting the flow of the raw-material gas and discharging the raw-material gas toward the interior space 100a are formed.

As a result, in the raw-material gas supply section 200 in the exemplary embodiment, it becomes possible to diffuse the raw-material gas, which has been introduced from the raw-material gas introduction section 202, in the Y-direction (the −Y-direction), and also, it becomes possible to bring the raw-material gas, which has been supplied from the raw-material gas supply duct 201 to the interior space 100a, into the state where the flow rate thereof is substantially uniform from the upstream side in the Y-direction to the downstream side in the Y-direction. This makes it possible to suppress occurrence of the vortex or fluctuations in the flow of the raw-material gas in the interior space 100a, and to suppress occurrence of floating upward of the raw-material gas or inclusion of the reaction products into the raw-material gas.

Further, in the raw-material gas supply section 200 of the exemplary embodiment, since the raw-material gas supply duct 201 has the above-described configuration (in particular, since the first duct angle θ1 is an obtuse angle), it becomes possible to reduce the diffusion length Lb while maintaining the size of the discharge width Wd constant. Accordingly, as compared to the case where the present configuration is not employed, it becomes possible to reduce the length of the raw-material gas supply duct 201 along the X-direction, and to achieve space savings in the raw-material gas supply section 200 and the CVD device 1. This is especially effective in a device for forming a film on a large-sized substrate S, with the diameter of not less than 6 inches, which tends to have a large discharge width Wd.

Moreover, as described above, in the CVD device 1 of the exemplary embodiment, the discharge width Wd in the raw-material gas supply duct 201 and the interior width W in the interior space 100a are equal. This makes it possible to supply the interior space 100a with the raw-material gas in the state of being diffused to the interior width W along the Y-direction. As a result, for example, even in the case where the film is formed on the large-sized substrate with the diameter of not less than 6 inches, as compared to the case where the present configuration is not employed along the Y-directionw, it becomes possible to equalize the concentration of the raw-material gas (the silicon-containing gas and the carbon-containing gas), to supply thereof to the interior space 100a.

Further, in the raw-material gas supply duct 201 of the exemplary embodiment, in each supply space (each of the first supply space 211 to the fourth supply space 241), the diffusion plate (each of the first diffusion plate 212 to the fourth diffusion plate 242) is provided. Accordingly, even in the case where the discharge width Wd is large, such as in the case where the film is formed on the large-sized substrate of not less than 6 inches, with respect to the raw-material gas supplied from the raw-material gas supply duct 201 to the interior space 100a, it is possible to prevent the concentration of the raw-material gas from becoming high at the center portion in the Y-direction due to occurrence of imbalances in the flow thereof. As a result, as compared to the case where the present configuration is not employed, with respect to the raw-material gas supplied to the interior space 100a, it becomes possible to equalize the concentration along the Y-direction thereof.

Still further, in the exemplary embodiment, by providing the flow-adjusting member 170 configured with the first dividing member 171 to the third dividing member 173 in the interior space 100a in the container chamber 100 that contains the substrate S, the interior space 100a was divided into the first region A1 to the fifth region A5. Then, in the fifth region A5 where the substrate S was arranged, the raw-material gas was supplied along the X-direction from the lateral side of the fifth region A5, and the first blocking gas Gb1 to the fourth blocking gas Gb4 were supplied along the −Z-direction, which is headed for the fifth region A5, from the first region A1 to the fourth region A4, respectively. Accordingly, when the raw-material gas is supplied to the interior space 100a, which is wider and has lower pressure than the raw-material gas supply duct 201, it is possible to suppress expansion of the second raw-material gas containing the silicon-containing gas and the third raw-material gas containing the carbon-containing gas to the upper side. This makes it possible to supply the film-formation surface of the SiC film on the substrate S efficiently with the silicon-containing gas and the carbon-containing gas.

Further, with the above-described configuration, it is possible to suppress movement of the raw-material gas toward the upper side in the interior space 100a, and to prevent the raw-material gas from reaching the ceiling 120 positioned on the upper side of the interior space 100a. Consequently, it is possible to suppress adhesion of the reaction products to the ceiling 120 due to reaction of the raw-material gas in the vicinity of the ceiling 120. Therefore, it is possible to make an accident that the reaction products from the ceiling 120 fall onto the substrate S less likely to occur.

Then, with the above-described configuration, it is possible to improve yields of the SiC epitaxial wafer produced by use of the CVD device 1 of the exemplary embodiment.

It should be noted that the first diffusion plate 212 to the fourth diffusion plate 242 are provided in the first supply space 211 to the fourth supply space 241, respectively, in the raw-material gas supply section 200 of the exemplary embodiment; but the first diffusion plate 212 to the fourth diffusion plate 242 are not necessarily provided. However, for equalizing the flow rate along the Y-direction of the raw-material gas supplied from the raw-material gas supply duct 201 to the interior space 100a, it is preferable to provide the first diffusion plate 212 to the fourth diffusion plate 242. If the first diffusion plate 212 to the fourth diffusion plate 242 are not provided, diffusion of the raw-material gas in the Y-direction (the −Y-direction) becomes insufficient and the flow rate of the raw-material gas at the end portion of the upstream side in the Y-direction and at the end portion of the downstream side in the Y-direction becomes low, as compared to that at the center portion in the Y-direction, in some cases.

Moreover, in the exemplary embodiment, the shape of the first diffusion plate 212 to the fourth diffusion plate 242 as viewed from the Z-direction was a square; however, the shape of the first diffusion plate 212 to the fourth diffusion plate 242 is not limited thereto, and a triangular shape having the base along the Y-direction, a linear shape along the Y-direction, or the like can be selected appropriately.

Further, in the raw-material gas supply section 200 of the exemplary embodiment, the first flow-adjusting member 213 to the fourth flow-adjusting member 243 are provided in the first supply space 211 to the fourth supply space 241, respectively, but are not necessarily provided. However, on the point that, with respect to the raw-material gas supplied from the raw-material gas supply section 200 to the interior space 100a, occurrence of the vortex or the like can be better suppressed, it is preferable to provide the first flow-adjusting member 213 to the fourth flow-adjusting member 243.

Moreover, in the exemplary embodiment, it was assumed that the discharge width Wd in the raw-material gas supply duct 201 and the interior width W in the container chamber 100 are equal; however, these are not required to be completely equal.

Still further, in the exemplary embodiment, it was assumed that each of the first upstream section 256a, the first middle section 256b and the first downstream section 256c constituting the first duct side wall 256 and each of the second upstream section 257a, the second middle section 257b and the second downstream section 257c constituting the second duct side wall 257, of the raw-material gas supply duct, was a flat surface; however, each of them is not necessarily a flat surface, but may be a curved surface.

However, with respect to the first downstream section 256c and the second downstream section 257c, in particular, for equalizing the moving direction or the flow rate along the Y-direction of the raw-material gas supplied from the raw-material gas supply duct 201 to the interior space 100a, it is preferable to form the first downstream section 256c and the second downstream section 257c along the XZ plane.

Moreover, in the exemplary embodiment, the first duct dividing wall 253, the second duct dividing wall 254 and the third duct dividing wall 255 are provided in the raw-material gas supply duct 201, to thereby divide the inside of the raw-material gas supply duct 201 into four spaces, namely, the first supply space 211, the second supply space 221, the third supply space 231 and the fourth supply space 241. Then, the first raw-material gas to the fourth raw-material gas are supplied to the interior space 100a, via these spaces, in the layered state.

However, in the CVD device 1 in the exemplary embodiment, from the viewpoint that the first duct angle θ1 is formed as an obtuse angle and the diffusion region for diffusing the raw-material gas in the Y-direction (the −Y-direction) and the discharge region for adjusting the flow of the raw-material gas and discharging thereof toward the interior space 100a are formed in the raw-material gas supply duct 201, the raw-material gas supply duct 201 is not necessarily divided into the plural spaces. For example, it may be possible that the raw-material gas supply duct 201 includes only one space for supplying the interior space 100a with the raw-material gas, and the carrier gas such as hydrogen, the carbon-containing gas and the silicon-containing gas are supplied to the interior space 100a, in the state of being mixed in advance, via the one space.

It should be noted that, in the exemplary embodiment, description was given by taking the case of epitaxially growing the 4H—SiC film on the substrate S configured with the SiC single crystal as an example; however, the crystal structure and the like of the substrate S or SiC to be grown on the substrate S are not limited thereto, but design changes may adequately be carried out.

Moreover, in the exemplary embodiment, description was given of the CVD device 1 of a so-called face-up type, in which the substrate S was loaded so that the formation surface for the SiC film faces upward in the interior space 100a and the first blocking gas to the fourth blocking gas were supplied from the upper side to the lower side.

However, as long as the positional relation of the first supply space 211 to the fourth supply space 241 and the first blocking gas supply section 310 to the fourth blocking gas supply section 340 with respect to the substrate S and the heating mechanism 500 that heats the substrate S is same, the present invention is able to be applied to a device of a so-called face-down type, in which the substrate S is loaded so that the formation surface for the SiC film faces downward, and the above-described effect can be obtained.

Still further, in the exemplary embodiment, a so-called sheet-fed type, in which the substrate S is contained in the container chamber 100 one by one, was employed; however, there is no limitation thereto, and a batch type, in which plural substrates S are contained for collective film formation, may be employed.

### REFERENCE SIGNS LIST

1 . . . CVD device

10 . . . Reaction container

100 . . . Container chamber

100a . . . Interior space

110 . . . Floor section

111 . . . Fixing section

112 . . . Rotating table

113 . . . Loading body

120 . . . Ceiling

130 . . . First side wall

140 . . . Second side wall

150 . . . Third side wall

160 . . . Fourth side wall

170 . . . Flow-adjusting section

171 . . . First dividing member

172 . . . Second dividing member

173 . . . Third dividing member

200 . . . Raw-material gas supply section

201 . . . Raw-material gas supply duct

202 . . . Raw-material gas introduction section

203 . . . Cooling section

200a . . . Supply space

300 . . . Blocking gas supply section

310 . . . First blocking gas supply section

320 . . . Second blocking gas supply section

330 . . . Third blocking gas supply section

340 . . . Fourth blocking gas supply section

400 . . . Discharge duct

400a . . . Discharge space

500 . . . Heating mechanism

600 . . . Used gas discharge section

800 . . . Rotational driving section

A1 . . . First region

A2 . . . Second region

A3 . . . Third region

A4 . . . Fourth region

A5 . . . Fifth region

1-7. (canceled)

8. An SiC-film formation device comprising:
a container chamber that has an interior space, and contains a substrate so that an SiC-film formation surface thereof is exposed to the interior space;
a heating unit that heats the substrate from a direction opposite to the SiC-film formation surface;
a carbon raw-material gas supply unit that supplies the interior space with a carbon raw-material gas containing carbon, which serves as a material for the SiC film, along a first direction from a lateral side of the substrate toward the substrate;
a silicon raw-material gas supply unit that supplies the interior space with a silicon raw-material gas containing silicon, which serves as a material for the SiC film, along the first direction from the lateral side of the substrate toward a side farther than the carbon raw-material gas when viewed from the SiC-film formation surface of the substrate; and
a blocking gas supply unit that supplies the interior space with a blocking gas along a second direction from a side facing the SiC-film formation surface toward the SiC-film formation surface, the blocking gas suppressing movement of the carbon raw-material gas and the silicon raw-material gas toward an upstream side in the second direction.

9. The SiC-film formation device according to claim 8, further comprising:
an assist gas supply unit that supplies the interior space with an assist gas along the first direction from the lateral side of the substrate toward at least one of a side closer than the carbon raw-material gas and a side farther than the silicon raw-material gas when viewed from the SiC-film formation surface of the substrate, the assist gas assisting the carbon raw-material gas and the silicon raw-material gas in moving toward the first direction.

10. The SiC-film formation device according to claim 8, wherein the carbon raw-material gas contains propane gas, the silicon raw-material gas contains monosilane gas, and the blocking gas contains hydrogen gas.

11. The SiC-film formation device according to claim 9, wherein the carbon raw-material gas contains propane gas, the silicon raw-material gas contains monosilane gas, and the blocking gas contains hydrogen gas.

12. An SiC-film formation device comprising:
a container chamber that has an interior space, and contains a substrate on a lower side in the interior space so that an SiC-film formation surface thereof faces upward; and
a raw-material gas supply section that supplies the interior space of the container chamber with a raw-material gas, which serves as a material for the SiC film, wherein the container chamber comprises:
a heater that heats the substrate; and
an inert gas supply section that supplies the interior space with an inert gas, which is inactive for the raw-material gas, along a second direction from an upper side toward a lower side, and
the raw-material gas supply section comprises:
a carbon raw-material gas supply route that supplies the interior space with a carbon raw-material gas containing carbon, which serves as a material for the SiC film, along a first direction from a lateral side of the substrate toward the substrate; and
a silicon raw-material gas supply route that is placed above the carbon raw-material gas supply route and supplies the interior space with a silicon raw-material gas containing silicon, which serves as a material for the SiC film, along the first direction.

13. The SiC-film formation device according to claim 12, wherein the raw-material gas supply section further comprises a cooling unit that cools the raw-material gas to be supplied to the interior space from the carbon raw-material gas supply route side.

14. The SiC-film formation device according to claim 12, wherein
the raw-material gas supply section further comprises:
a first assist gas supply route that is provided below the carbon raw-material gas supply route and supplies a first assist gas along the first direction, the first assist gas assisting the carbon raw-material gas in moving toward the first direction; and
a second assist gas supply route that is provided above the silicon raw-material gas supply route and supplies a second assist gas along the first direction, the second assist gas assisting the silicon raw-material gas in moving toward the first direction.

15. The SiC-film formation device according to claim 13, wherein
the raw-material gas supply section further comprises:
a first assist gas supply route that is provided below the carbon raw-material gas supply route and supplies a first assist gas along the first direction, the first assist gas assisting the carbon raw-material gas in moving toward the first direction; and
a second assist gas supply route that is provided above the silicon raw-material gas supply route and supplies a second assist gas along the first direction, the second assist gas assisting the silicon raw-material gas in moving toward the first direction.

16. A method for producing an SiC film, comprising:
heating a substrate, which is contained in a container chamber having an interior space so that an SiC-film formation surface thereof is exposed to the interior space, from a direction opposite to the SiC-film formation surface;
supplying the interior space with a carbon raw-material gas containing carbon, which serves as a material for the SiC film, along a first direction from a lateral side of the substrate toward the substrate;
supplying the interior space with a silicon raw-material gas containing silicon, which serves as a material for the SiC film, along the first direction from the lateral side of the substrate toward a side farther than the carbon raw-material gas when viewed from the SiC-film formation surface of the substrate; and
supplying the interior space with a blocking gas along a second direction from a side facing the SiC-film formation surface toward the SiC-film formation surface, the blocking gas suppressing movement of the carbon raw-material gas and the silicon raw-material gas toward an upstream side in the second direction.
